(19) United States
(12) Patent Application Publication
(10) Pub. No.: US 2024/0282817 A1
(43) Pub. Date: Aug. 22, 2024

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Yuuki ODA, Matsumoto-city (JP); Atsushi ONOGAWA, Matsumoto-city (JP); Tohru SHIRAKAWA, Matsumoto-city (JP)

(21) Appl. No.: 18/389,836

(22) Filed: Dec. 20, 2023

(30) Foreign Application Priority Data
Feb. 16, 2023 (JP) 2023-022105

(51) Int. Cl. H01L 29/06; H01L 29/66; H01L 29/739

(52) U.S. Cl. CPC H01L 29/0696; H01L 29/66325; H01L 29/7393; H01L 29/0619

(57) ABSTRACT

Provided is a semiconductor device which includes a transistor portion and a diode portion, including: a drift region of a first conductivity type which is provided in a semiconductor substrate; a plurality of trench portions which are provided on a front surface of the semiconductor substrate; a buffer region of the first conductivity type which is provided on a side of a back surface of the semiconductor substrate with respect to the drift region; a first lifetime control region which is provided in the transistor portion; and a second lifetime control region which is provided at a depth different from that of the first lifetime control region in the diode portion.

The contents of the following patent application(s) are incorporated herein by reference:
NO. 2023-022105 filed in JP on Feb. 16, 2023

### BACKGROUND

### 1. Technical Field

The present invention relates to a semiconductor device and a manufacturing method of the semiconductor device.

### 2. Related Art

Conventionally, a semiconductor device including a transistor portion and a diode portion is known (for example, see Patent Documents 1 and 2).
Patent Document 1: International Publication No. 2019/098270
Patent Document 2: International Publication No. 2018/110703

### BRIEF DESCRIPTION OF THE DRAWINGS

FIG. 1 illustrates an example of a top view of a semiconductor device 100.

FIG. 2A illustrates an enlarged view of a region A in FIG. 1.

FIG. 2B illustrates a view showing an example of an XZ cross section including an a-a′ cross section in FIG. 2A.

FIG. 3A illustrates a concentration distribution in a depth direction of a semiconductor substrate 10.

FIG. 3B illustrates an example of a flowchart of a manufacturing method of the semiconductor device 100.

FIG. 4A illustrates a relationship between a depth of a lifetime control region and a leakage current density.

FIG. 4B illustrates the relationship between the depth of the lifetime control region and the leakage current density.

FIG. 5A illustrates a relationship between the depth of the lifetime control region and a leakage current.

FIG. 5B illustrates the relationship between the depth of the lifetime control region and the leakage current.

FIG. 6 illustrates a diagram for describing a conditional expression of the depth of the lifetime control region.

FIG. 7A illustrates a diagram for describing a method of calculating a parameter B.

FIG. 7B illustrates a diagram for describing a method of calculating a parameter B.

FIG. 8A illustrates a top view of a modification of the semiconductor device 100.

FIG. 8B illustrates a view showing an example of an XZ cross section including a b-b′ cross section in FIG. 8A.

FIG. 9A illustrates a top view of a modification of the semiconductor device 100.

FIG. 9B illustrates a view showing an example of an XZ cross section including a c-c′ cross section in FIG. 9A.

FIG. 10 illustrates a view showing a modification of the XZ cross section including the c-c′ cross section in FIG. 9A.

FIG. 11 illustrates an example of a helium ion implantation process using a mask 210.

FIG. 12A illustrates dependency of a forward voltage VF on a depth of a second lifetime control region 152.

FIG. 12B illustrates dependency of a turn-on loss Eon on the depth of the second lifetime control region 152.

FIG. 12C illustrates dependency of a switching loss Err during reverse recovery on the depth of the second lifetime control region 152.

FIG. 13A illustrates dependency of the turn-off loss Eoff on a depth of a first lifetime control region 151.

FIG. 13B illustrates dependency of a collector-emitter saturation voltage Vce (sat) on the depth of the first lifetime control region 151.

FIG. 14 illustrates an example of improving a trade-off relationship of characteristics of the semiconductor device 100.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor, an Si-i-H defect which is a combination of interstitial silicon (Si-i) and hydrogen, or a CiOi-H defect which is a combination of interstitial carbon (Ci), interstitial oxygen (Oi), and hydrogen functions as the donor that supplies electrons. In the present specification, these defects may be referred to as the hydrogen donor.

In the present specification, a description of a P+ type or an N+ type means a higher doping concentration than that of the P type or the N type, and a description of a P-type or an N-type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. A carrier means an electron charge carrier or a hole charge carrier. The carrier concentration measured by the CV profiling or the SRP method may be a value in a thermal equilibrium state. Further, in a region of the N type, the donor concentration is sufficiently higher than the acceptor concentration, and thus the carrier concentration of the region may be set as the donor concentration. Similarly, in a region of the P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like. The carrier concentration becomes lower for the following reason. In the SRP method, a spreading resistance is measured, and a carrier concentration is converted from a measurement value of the spreading resistance. At this time, mobility of the crystalline state is used as the carrier mobility. On the other hand, despite the fact that carrier mobility is reduced at a position where the lattice defect is introduced, the carrier concentration is calculated by using the carrier mobility of the crystalline state. Therefore, a value lower than an actual carrier concentration, i.e., a concentration of donors or acceptors, is obtained.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be represented by cm (centimeter). In this case, various calculations may be converted into m (meter) to be calculated. Regarding indication of numerical values meaning a power of 10, for example, indication of 1E+16 means 1×10¹⁶, and indication of 1E−16 means 1×10⁻¹⁶.

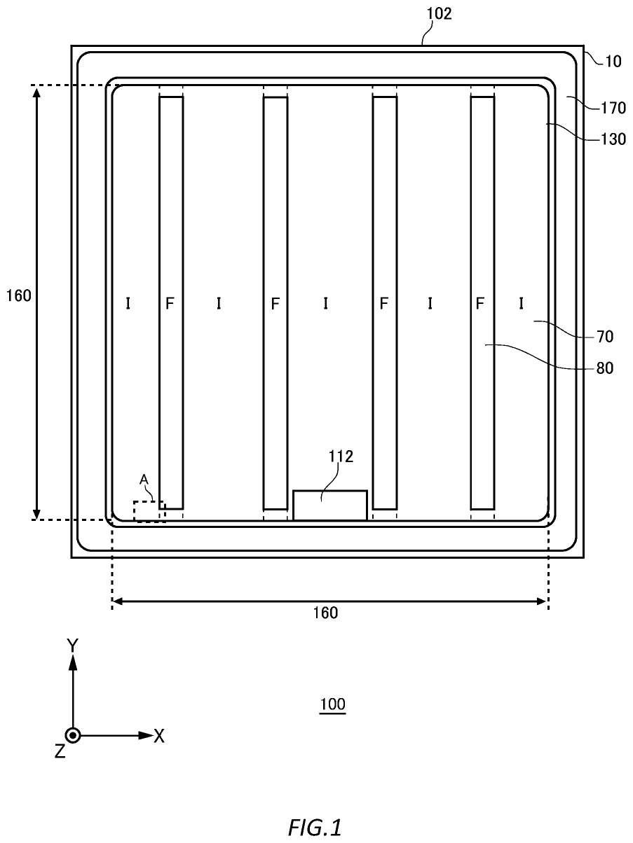

FIG. 1 shows an example of a top view of a semiconductor device 100. FIG. 1 shows a position at which each member is projected on an upper surface of a semiconductor substrate 10. FIG. 1 shows merely some members of the semiconductor device 100, and omits illustrations of some members. The semiconductor device 100 is a semiconductor chip including a transistor portion 70 and a diode portion 80.

The transistor portion 70 includes a transistor such as an IGBT (Insulated Gate Bipolar Transistor). The diode portion 80 includes a diode such as a free wheel diode (FWD). The semiconductor device 100 of this example is a reverse conducting IGBT (RC-IGBT) having a transistor portion 70 and a diode portion 80 on the same chip.

The semiconductor substrate 10 is a substrate that is formed of a semiconductor material. The semiconductor substrate 10 may be a silicon substrate, may be a silicon carbide substrate, may be a diamond substrate, may be a nitride semiconductor substrate such as gallium nitride, may be an inorganic compound semiconductor substrate such as gallium oxide, or may be an organic compound semiconductor substrate. The semiconductor substrate 10 in this example is a silicon substrate. The semiconductor substrate 10 may be a wafer which has been cut out from a semiconductor ingot, or may be a chip into which a wafer is singulated. The semiconductor ingot may be manufactured by any one of a Czochralski method (CZ method), a magnetic field applied Czochralski method (MCZ method), or a float zone method (FZ method).

The semiconductor substrate 10 has an end side 102 in the top view. When merely referred to as the top view in the present specification, it means that the semiconductor substrate 10 is viewed from an upper surface side. The semiconductor substrate 10 of this example has two sets of end sides 102 opposite to each other in the top view. In FIG. 1, the X axis and the Y axis are parallel to any of the end sides 102. In addition, the Z axis is perpendicular to the upper surface of the semiconductor substrate 10. The semiconductor substrate 10 includes an active portion 160 and an edge termination structure portion 170.

The active portion 160 is a region where a main current flows in the depth direction between the upper surface and the lower surface of the semiconductor substrate 10 during the operation of the semiconductor device 100. An emitter electrode is provided above the active portion 160, but is omitted in FIG. 1.

The active portion 160 is provided with at least one of a transistor portion 70 including a transistor element such as an IGBT, and a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10.

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in the top view may be referred to as an extending direction (the Y axis direction in FIG. 1). Each of the transistor portions 70 and the diode portions 80 may have a longitudinal length in the extending direction. In other words, the length of each of the transistor portions 70 in the Y axis direction is larger than the width in the X axis direction. Similarly, the length of each of the diode portions 80 in the Y axis direction is larger than the width in the X axis direction. The extending direction of the transistor portion 70 and the diode portion 80, and the longitudinal direction of each trench portion described later may be the same.

Each of the diode portions 80 includes a cathode region of N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. In a region other than the cathode region on the lower surface of the semiconductor substrate 10, a P+ type collector region may be provided.

The transistor portion 70 has the collector region of the P+ type in a region in contact with the lower surface of the semiconductor substrate 10. Further, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of this example has a gate pad 112. The semiconductor device 100 may have a pad such as an anode pad, a cathode pad, and a current detection pad. Each pad is arranged in a region close to the end side 102. The region close to the end side 102 refers to a region between the end side 102 and the emitter electrode in the top view. When the semiconductor device 100 is mounted, each pad may be connected to an external circuit via a wiring such as a wire.

A gate potential is applied to the gate pad 112. The gate pad 112 is electrically connected to a conductive portion of a gate trench portion of the active portion 160. The semiconductor device 100 includes a gate runner 130 that connects the gate pad 112 and the gate trench portion.

The gate runner 130 is electrically connected to the gate conductive portion of the transistor portion 70 and applies a gate voltage to the transistor portion 70. The gate runner 130 is provided so as to enclose an outer circumference of the active portion 160 in the top view. The gate runner 130 is electrically connected to the gate pad 112 provided in the edge termination structure portion 170.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 of this example includes an edge termination structure portion 170 between the active portion 160 and the end side 102 in the top view. The edge termination structure portion 170 of this example is arranged between the gate runner 130 and the end side 102. The edge termination structure portion 170 reduces an electric field strength on the upper surface side of the semiconductor substrate 10. The edge termination structure portion 170 may include at least one of a guard ring, a field plate, or a RESURF annularly provided to enclose the active portion 160.

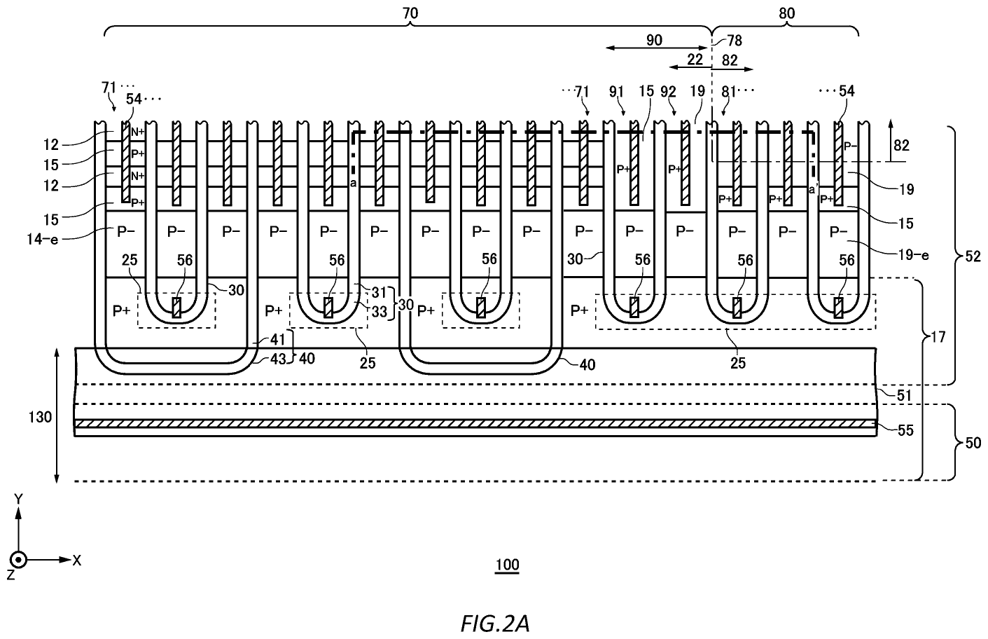

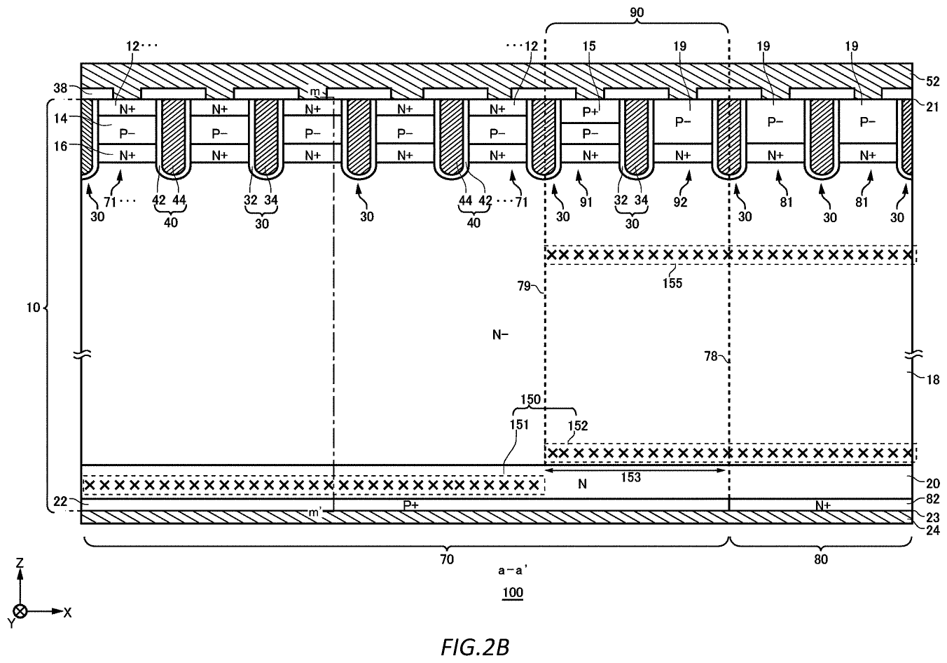

FIG. 2A illustrates an enlarged view of a region A in FIG. 1. The region A is a region including the transistor portion 70, the diode portion 80, and the gate runner 130. The gate runner 130 of this example includes a gate metal layer 50 and a gate runner portion 51.

A boundary region 90 is provided between the transistor portion 70 and the diode portion 80 on the front surface of the semiconductor substrate 10. The front surface 21 of the semiconductor substrate 10 refers to one of the two principal surfaces opposite to each other in the semiconductor substrate 10. The front surface 21 will be described below.

The semiconductor device 100 of this example includes a gate trench portion 40, a dummy trench portion 30, a well region 17, an emitter region 12, a base region 14, and a contact region 15 that are formed inside the front surface 21 side of the semiconductor substrate 10. In addition, the semiconductor device 100 in this example includes an emitter electrode 52 and a gate metal layer 50 which are provided above the front surface 21 of the semiconductor substrate 10. The emitter electrode 52 and the gate metal layer 50 are provided separated from each other.

An interlayer dielectric film is formed between the emitter electrode 52 and the gate metal layer 50, and the front surface 21 of the semiconductor substrate 10, but the interlayer dielectric film is omitted in FIG. 2A. In the interlayer dielectric film of this example, a contact hole 54, a contact hole 55 and a contact hole 56 are formed to pass through the interlayer dielectric film.

The emitter electrode 52 is electrically connected to the emitter region 12, the contact region 15, and the base region 14 on the front surface 21 of the semiconductor substrate 10 via the contact hole 54 formed in the interlayer dielectric film. Also, the emitter electrode 52 is connected with dummy conductive portions in the dummy trench portions 30 via the contact hole 56. A connection portion 25 formed of a conductive material such as polysilicon doped with impurities may be provided between the emitter electrode 52 and the dummy conductive portion.

The gate metal layer 50 is in contact with the gate runner portion 51 via the contact hole 55. The gate runner portion 51 is formed of a semiconductor such as polysilicon doped with impurities. The gate runner portion 51 is connected to a gate conductive portion in the gate trench portion 40 on the front surface of the semiconductor substrate 10.

The emitter electrode 52 and the gate metal layer 50 are formed of a material including metal. At least a partial region of the emitter electrode 52 may be formed of metal such as aluminum (Al) or a metal alloy such as an aluminum-silicon alloy (AlSi) and an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may include a barrier metal formed of titanium, titanium compound, or the like, which underlies a region formed of aluminum or the like. Further, each electrode may include a plug, which is formed by embedding tungsten or the like so as to be in contact with the barrier metal and aluminum or the like, in the contact hole.

The well region 17 is provided so as to overlap with the gate metal layer 50 and the gate runner portion 51. The well region 17 is provided to extend at a predetermined width also in a range not overlapping with the gate metal layer 50 and the gate runner portion 51. The well region 17 of this example is provided away from an end of the contact hole 54 in the Y axis direction to the gate metal layer 50 side. The well region 17 is a region of a second conductivity type having a higher doping concentration than the base region 14. The base region 14 in this example is a P-type, and the well region 17 is a P+ type.

Each of the transistor portion 70 and the diode portion 80 includes a plurality of trench portions arrayed in an array direction on the front surface 21 of the semiconductor substrate 10. In the transistor portion 70 of this example, one or more gate trench portions 40 and one or more dummy trench portions 30 are alternately provided along the array direction. In the diode portion 80 of this example, the plurality of dummy trench portions 30 are provided along the array direction. In the diode portion 80 of this example, the gate trench portion 40 is not provided.

In the transistor portion 70, one or more gate trench portions 40 are arrayed at a predetermined interval along the array direction of each trench. The gate conductive portion inside the gate trench portion 40 is electrically connected to the gate metal layer 50 to be applied by a gate potential. In the transistor portion 70, one or more dummy trench portions 30 may be arrayed at a predetermined interval along the array direction. A potential different from the gate potential is applied to the dummy conductive portion inside the dummy trench portion 30. The dummy conductive portion of this example is electrically connected to the emitter electrode 52 to be applied by an emitter potential.

In the transistor portion 70, one or more gate trench portions 40 and one or more dummy trench portions 30 may be formed alternately along the array direction. Also, the dummy trench portions 30 are arrayed in the diode portion 80 and the boundary region 90 at a predetermined interval along the array direction. Note that the transistor portion 70 may alternatively be constituted only by the gate trench portion 40 without the dummy trench portion 30 being provided.

The gate trench portion 40 of this example may have two extending portions 41 extending along the extending direction perpendicular to the array direction (portions of a trench that are linear along the extending direction), and a connecting portion 43 connecting the two extending portions 41. The extending direction in FIG. 2A is the Y axis direction.

Preferably, at least a part of the connecting portion 43 is provided in a curved shape in the top view. By the connecting portion 43 connecting the end portions of two extending portions 41 in the Y axis direction to each other, it is possible to reduce the electric field strength at the end portions of the extending portions 41.

In the transistor portion 70, the dummy trench portions 30 are provided between the extending portions 41 of the gate trench portions 40. Between the extending portions 41, one dummy trench portion 30 may be provided, or a plurality of dummy trench portions 30 may be provided. The dummy trench portion 30 may have a linear shape extending in the extending direction, or may have extending portions 31 and a connecting portion 33 similarly to the gate trench portion 40. The semiconductor device 100 may include both of the linear dummy trench portion 30 having no connecting portion 33 and the dummy trench portion 30 having the connecting portion 33. A direction in which the extending portions 41 of the gate trench portion 40 or the extending portions 31 of the dummy trench portion 30 extend to be long in the extending direction is referred to as a longitudinal direction of the trench portion. The longitudinal direction of the gate trench portion 40 or the dummy trench portion 30 may match the extending direction. In this example, the extending direction and the longitudinal direction are the Y axis directions. The array direction in which the plurality of gate trench portions 40 or the dummy trench portions 30 are arrayed is referred to as a lateral direction of the trench portion. The lateral direction may match the array direction. The lateral direction may also be perpendicular to the longitudinal direction. In this example, the lateral direction is perpendicular to the longitudinal direction. In this example, the array direction and the lateral direction are the X axis directions.

In the connecting portion 43 at the tip of the gate trench portion 40, the gate conductive portion inside the gate trench portion 40 are connected to the gate runner portion 51. The gate trench portion 40 may be provided to protrude to the gate runner portion 51 side with respect to the dummy trench portion 30 in the extending direction (Y axis direction). The protruding portion of the gate trench portion 40 is connected to the gate runner portion 51.

A diffusion depth of the well region 17 may be deeper than depths of the gate trench portion 40 and the dummy trench portion 30. The end portions of the gate trench portion 40 and the dummy trench portion 30 in the Y axis direction are provided in the well region 17 in the top view. In other words, at the end portion of each trench portion in the Y axis direction, the bottom portion of each trench portion in the depth direction is covered with the well region 17. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion of this example is provided extending in the extending direction (Y axis direction) along the trench portion, on the upper surface of the semiconductor substrate 10.

The boundary region 90 is provided in direct contact with the diode portion 80 in the transistor portion 70. The boundary region 90 may be a region having the dummy trench portion 30 and provided with the collector region 22 on the back surface side of the semiconductor substrate 10. Each of both end portions, in a trench array direction, of the mesa portion included in the boundary region 90 may be in contact with the dummy trench portion 30. The trench portions of the boundary region 90 may be all dummy trench portions 30. The boundary region 90 may include the gate trench portion 40. In the boundary region 90 of this example, the emitter region 12 of the first conductivity type is not provided in the mesa portion on the front surface side of the semiconductor substrate 10. The boundary region 90 may have the base region 14, or may have an anode region 19 on the front surface 21. The boundary region 90 may have the emitter region 12 or the contact region 15 on the front surface 21. The boundary region 90 of this example includes the base region 14, the anode region 19, and the contact region 15 on the front surface 21. Note that FIG. 2A illustrates the positions of the collector region 22 and the cathode region 82 provided on the back surface side of the semiconductor substrate 10 when projected on the front surface side.

A mesa portion 71 is a mesa portion provided in the transistor portion 70. A mesa portion 81 is a mesa portion provided in the diode portion 80. A mesa portion 91 and a mesa portion 92 are mesa portions provided in the boundary region 90. When merely referred to as the mesa portion in the present specification, it means each of the mesa portion 71, the mesa portion 81, the mesa portion 91, or the mesa portion 92. The mesa portion may be a portion of the semiconductor substrate 10 sandwiched between two trench portions adjacent to each other, and may be a portion ranging from the front surface 21 of the semiconductor substrate 10 to the depth of the lowermost bottom portion of each trench portion. The extending portions of each trench portion may be regarded as one trench portion. That is, the region sandwiched between two extending portions may be set to be a mesa portion.

Each mesa portion is provided with the base region 14 or the anode region 19. In the base region 14 or the anode region 19 exposed on the upper surface of the semiconductor substrate 10 in the mesa portion, a region arranged closest to the gate metal layer 50 is defined as a base region 14-e or an anode region 19-e. While the base region 14-e or the anode region 19-e arranged at one end portion of each mesa portion in the extending direction is illustrated in FIG. 2A, the base region 14-e or the anode region 19-e is also arranged at the other end portion of each mesa portion. In each mesa portion, at least one of the emitter region 12 of the first conductivity type or the contact region 15 of the second conductivity type may be provided in a region sandwiched between the base region 14-e or the anode region 19-e in the top view. The emitter region 12 of this example is an N+ type, and the contact region 15 is a P+ type. The emitter region 12 and the contact region 15 may be provided between the base region 14 and the upper surface of the semiconductor substrate 10 in the depth direction.

The mesa portion 71 of the transistor portion 70 has the emitter region 12 exposed on the upper surface of the semiconductor substrate 10. The emitter region 12 is provided in contact with the gate trench portion 40. The mesa portion 71 in contact with the gate trench portion 40 may be provided with the contact region 15 exposed on the upper surface of the semiconductor substrate 10.

Each of the contact region 15 and the emitter region 12 in the mesa portion 71 is provided from one trench portion to the other trench portion in the X axis direction. As an example, the contact regions 15 and the emitter regions 12 of the mesa portion 71 are alternately arranged along the extending direction (Y axis direction) of the trench portion.

In another example, the contact region 15 and the emitter region 12 of the mesa portion 71 may be provided in a stripe shape along the extending direction (Y axis direction) of the trench portion. For example, the emitter region 12 is provided in a region in contact with the trench portion, and the contact region 15 is provided in a region sandwiched between the emitter regions 12.

The emitter region 12 is not provided in the mesa portion 81 of the diode portion 80, but the emitter region 12 may be provided. The anode region 19 is provided on the upper surface of the mesa portion 81. The contact region 15 may be provided on the upper surface of the mesa portion 81. In a region sandwiched between the anode regions 19-e on the upper surface of the mesa portion 81, the contact region 15 may be provided in contact with each anode region 19-e. The anode region 19 may be provided in a region sandwiched between the contact regions 15 on the upper surface of the mesa portion 81. The anode region 19 may be arranged in the entire region sandwiched between the contact regions 15 in the extending direction of the trench portion.

The contact hole 54 is provided above each mesa portion. The contact hole 54 is arranged in a region sandwiched between the base region 14-e or the anode region 19-e along the extending direction of the trench portion. The contact hole 54 of this example is provided above respective regions of the contact region 15, the base region 14, the anode region 19, and the emitter region 12. The contact hole 54 is not provided in regions corresponding to the base region 14-e, the anode region 19-e, and the well region 17. The contact hole 54 may be arranged at the center of the mesa portion 71 in the trench array direction (X axis direction).

In the diode portion 80, a cathode region 82 of the N+ type is provided in a region in direct contact with the lower surface of the semiconductor substrate 10. A doping concentration of the cathode region 82 is higher than a doping concentration of the drift region 18. On the lower surface of the semiconductor substrate 10, a collector region of the P+ type 22 may be provided in a region where the cathode region 82 is not provided. The cathode region 82 and the collector region 22 are provided between a back surface 23 of the semiconductor substrate 10 and a buffer region 20 to be described below. In FIG. 2A, a boundary 78 between the cathode region 82 and the collector region 22 is indicated by a broken line.

The cathode region 82 is arranged away from the well region 17 in the Y axis direction. With this configuration, it is possible to secure a distance between the P type region (well region 17) that has a relatively high doping concentration and is formed to a deep position and the cathode region 82, improve a breakdown voltage, and suppress implantation of holes from the well region 17. The end portion of the cathode region 82 of this example in the Y axis direction is arranged farther away from the well region 17 than the end portion of the contact hole 54 in the Y axis direction. In another example, the end portion of the cathode region 82 in the Y axis direction may be arranged between the well region 17 and the contact hole 54.

The contact region 15 is provided in the mesa portion 91 of the boundary region 90. The anode region 19 is provided in the mesa portion 92 of the boundary region 90. The mesa portion 91 may be provided on the transistor portion 70 side of the boundary region 90. The mesa portion 91 may be provided in the boundary region 90 in contact with the mesa portion 71. The mesa portion 92 may be provided on the diode portion 80 side of the boundary region 90. The mesa portion 92 may be provided in the boundary region 90 in contact with the diode portion 80.

FIG. 2B illustrates a view showing an example of an XZ cross section including an a-a′ cross section in FIG. 2A. The XZ cross section including the a-a′ cross section is an XZ plane that passes through the emitter region 12 in the transistor portion 70. The semiconductor device 100 in this example has the semiconductor substrate 10, the interlayer dielectric film 38, the emitter electrode 52, and the collector electrode 24 in the XZ cross section including the a-a′ cross section. The emitter electrode 52 is formed above the semiconductor substrate 10 and the interlayer dielectric film 38.

The drift region 18 is a region of the first conductivity type which is provided in the semiconductor substrate 10. The drift region 18 in this example is of the N-type as an example. The drift region 18 may be a region that has remained without other doping regions being formed in the semiconductor substrate 10. That is, the doping concentration of the drift region 18 may be a doping concentration of the semiconductor substrate 10.

A buffer region 20 is a region of the first conductivity type which is provided on a back surface 23 side of the semiconductor substrate 10 with respect to the drift region 18. The buffer region 20 of this example is provided closer to the back surface 23 of the semiconductor substrate 10 than a center of the semiconductor substrate 10 in the depth direction. The buffer region 20 in this example is of the N type as an example. The doping concentration of the buffer region 20 is higher than the doping concentration of the drift region 18. The buffer region 20 may function as a field stop layer which prevents a depletion layer spreading from the lower surface side of the base region 14 from reaching the collector region 22 of the second conductivity type and the cathode region 82 of the first conductivity type.

The collector region 22 and the cathode region 82 are provided on the back surface 23 of the semiconductor substrate 10. The collector region 22 is provided below the buffer region 20 in the transistor portion 70. The cathode region 82 is provided below the buffer region 20 in the diode portion 80. The boundary 78 between the collector region 22 and the cathode region 82 may be a boundary between the transistor portion 70 and the diode portion 80.

The collector electrode 24 is formed at a back surface 23 of the semiconductor substrate 10. The collector electrode 24 is formed of a conductive material such as metal. For example, at least a partial region of the collector electrode 24 may be formed of metal such as aluminum (Al) or a metal alloy such as an aluminum-silicon alloy (AlSi) and an aluminum-silicon-copper alloy (AlSiCu).

The base region 14 is a region of the second conductivity type provided above the drift region 18 in the mesa portion 71 and the mesa portion 91. The base region 14 is provided in contact with the gate trench portion 40. The base region 14 may be provided in contact with the dummy trench portion 30.

The anode region 19 is a region of the second conductivity type provided above the drift region 18 in the mesa portion 92 and the mesa portion 81. The anode region 19 is provided in contact with the dummy trench portion 30. The anode region 19 may be provided in contact with the gate trench portion 40. The maximum value of the doping concentration of the anode region 19 may be less than or may be equal to the maximum value of the doping concentration of the base region 14. The maximum value of the doping concentration of the anode region 19 of this example is smaller than the maximum value of the doping concentration of the base region 14. In the depth direction of the semiconductor substrate 10, the depth of the anode region 19 may be shallower than or may be equal to the depth of the base region 14. The depth of the anode region 19 of this example is substantially equal to the depth of the base region 14. The integrated value obtained by integrating the doping concentration of the anode region 19 along the depth direction of the semiconductor substrate 10 may be smaller than or may be equal to the integrated value obtained by integrating the doping concentration of the base region 14. The integrated value of the doping concentration of the anode region 19 of this example is smaller than the integrated value of the doping concentration of the base region 14.

The emitter region 12 is provided on the front surface 21 side with respect to the drift region 18, and has a higher doping concentration than the drift region 18. The emitter region 12 of this example is provided above the base region 14 in the mesa portion 71. The emitter region 12 may be provided in contact with the gate trench portion 40. The emitter region 12 may or may not be in contact with the dummy trench portion 30. Moreover, the emitter region 12 may not be provided in the mesa portion 91.

The contact region 15 is provided above the base region 14 in the mesa portion 91. The contact region 15 is provided in contact with the gate trench portion 40 in the mesa portion 91. In another cross section, the contact region 15 may be provided at the front surface 21 in the mesa portion 71.

The accumulation region 16 is a region of the first conductivity type which is provided in the front surface 21 side of the semiconductor substrate 10 with respect to the drift region 18. The accumulation region 16 of this example is of the N+ type as an example. The accumulation region 16 is provided in the mesa portion 71. The accumulation region 16 may also be provided in the mesa portion 81 and the mesa portion 91.

In addition, the accumulation region 16 is provided in contact with the gate trench portion 40. The accumulation region 16 may be or may not be in contact with the dummy trench portion 30. The doping concentration of the accumulation region 16 is higher than the doping concentration of the drift region 18. Providing the accumulation region 16 can enhance the carrier injection enhancement effect (IE effect) to reduce an ON voltage of the transistor portion 70.

One or more gate trench portions 40 and one or more dummy trench portions 30 are provided at the front surface 21. Each trench portion is provided from the front surface 21 to the drift region 18. In the region where at least any of the emitter region 12, the base region 14, the contact region 15, or the accumulation region 16 is provided, each trench portion also penetrates these regions to reach the drift region 18. The configuration of the trench portion penetrating the doping region is not limited to the one manufactured in the order of forming the doping region and then forming the trench portion. The configuration of the trench portion penetrating the doping region includes a configuration of the doping region being formed between the trench portions after forming the trench portion.

The gate trench portion 40 has a gate trench, a gate dielectric film 42, and a gate conductive portion 44 which are formed in the front surface 21. The gate dielectric film 42 is formed to cover an inner wall of the gate trench. The gate dielectric film 42 may be formed by oxidizing or nitriding a semiconductor on the inner wall of the gate trench. Inside the gate trench, the gate conductive portion 44 is formed inside the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 in the front surface 21.

The gate conductive portion 44 includes a region opposing the adjacent base region 14 in the mesa portion 71 side by sandwiching the gate dielectric film 42 in a depth direction of the semiconductor substrate 10. When a predetermined voltage is applied to the gate conductive portion 44, a channel as an inversion layer of electrons is formed in the interfacial surface layer of the base region 14 that is in contact with the gate trench.

The dummy trench portion 30 may have the same structure as the gate trench portion 40. The dummy trench portion 30 has a dummy trench, a dummy dielectric film 32, and a dummy conductive portion 34 which are formed in the front surface 21 side. The dummy dielectric film 32 is formed covering the inner walls of the dummy trench. The dummy conductive portion 34 is formed in the interior of the dummy trench and also formed inside the dummy dielectric film 32. The dummy dielectric film 32 insulates the dummy conductive portion 34 from the semiconductor substrate 10. The dummy trench portion 30 is covered by the interlayer dielectric film 38 in the front surface 21.

The interlayer dielectric film 38 is provided at the front surface 21. The emitter electrode 52 is provided above the interlayer dielectric film 38. In the interlayer dielectric film 38, one or more contact holes 54 are provided for electrically connecting the emitter electrode 52 to the semiconductor substrate 10. Similarly, the contact hole 55 and the contact hole 56 may be provided to pass through the interlayer dielectric film 38.

A back-surface-side lifetime control portion 150 and a front-surface-side lifetime control portion 155 are provided in the semiconductor substrate 10 and include a lifetime killer. The back-surface-side lifetime control portion 150 and the front-surface-side lifetime control portion 155 may be regions in which a lifetime killer is intentionally formed by, for example, implanting impurities into the semiconductor substrate 10. In one example, the back-surface-side lifetime control portion 150 and the front-surface-side lifetime control portion 155 are formed by implanting helium into the semiconductor substrate 10. By providing the back-surface-side lifetime control portion 150 and the front-surface-side lifetime control portion 155, turn-off time or reverse recovery time is reduced, and a tail current is suppressed, so that a loss at the time of switching can be reduced.

The lifetime killer is a recombination center of carriers. The lifetime killer may be a lattice defect. For example, the lifetime killer may be a vacancy, a divacancy, a defect complex of these with elements constituting the semiconductor substrate 10, or dislocation. Furthermore, the lifetime killer may be a noble gas element such as helium and neon, a metal element such as platinum, or the like. The lifetime killer may be a recombination center formed closer to an implantation surface of the semiconductor substrate 10 than hydrogen that has stopped, after hydrogen ions are implanted into the implantation surface. An electron beam may be used for forming the lattice defect. The dose amount of impurities for forming the lifetime control portion may be 0.5E10 cm⁻² or more and 1.0E13 cm⁻² or less, or may be 5.0E10 cm⁻² or more and 5.0E11 cm⁻² or less. Acceleration energy for forming a lifetime control portion may be 100 keV or more and 100 MeV or less. When an electron beam is used to form lattice defects, the radiation amount of the electron beam may be 1 kGy or more and 5000 kGy or less.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements constituting the semiconductor substrate 10, or may be a dislocation concentration. Alternatively, the lifetime killer concentration may be a chemical concentration of the noble gas element such as helium and neon, or may be a chemical concentration of the metal element such as platinum.

The front-surface-side lifetime control portion 155 is provided on the front surface 21 side with respect to the center of the semiconductor substrate 10 in the depth direction. The front-surface-side lifetime control portion 155 is provided in the diode portion 80. The front-surface-side lifetime control portion 155 may be provided to extend from the diode portion 80 to the transistor portion 70 in the trench array direction. The front-surface-side lifetime control portion 155 of this example is provided to extend from the diode portion 80 to the boundary 79 in the trench array direction. With this configuration, implantation of carriers from the transistor portion 70 can be suppressed, and a reverse recovery loss can be reduced. Note that the boundary 79 is a boundary between the boundary region 90 and a region other than the boundary region 90 in the transistor portion 70. The front-surface-side lifetime control portion 155 may not be formed.

The back-surface-side lifetime control portion 150 is provided on the back surface 23 side with respect to the front-surface-side lifetime control portion 155. The back-surface-side lifetime control portion 150 may be provided on the back surface 23 side with respect to the center of the semiconductor substrate 10 in the depth direction, or may be provided on the front surface 21 side. In this example, the back-surface-side lifetime control portion 150 is provided on the back surface 23 side with respect to the center of the semiconductor substrate 10 in the depth direction. The back-surface-side lifetime control portion 150 may be provided closer to the back surface 23 than the center of the semiconductor substrate 10 in the depth direction. The back-surface-side lifetime control portion 150 may be provided in the buffer region 20 or may be provided above the buffer region 20. The back-surface-side lifetime control portion 150 includes a first lifetime control region 151 and a second lifetime control region 152. The first lifetime control region 151 and the second lifetime control region 152 of this example do not overlap with each other in the top view, but may overlap with each other.

The first lifetime control region 151 may be provided on the back surface 23 side with respect to the center of the semiconductor substrate 10 in the depth direction of the semiconductor substrate 10 in the transistor portion 70. The first lifetime control region 151 of this example is provided on the back surface 23 side with respect to the center of the semiconductor substrate 10 in the depth direction of the semiconductor substrate 10. The first lifetime control region 151 of this example is provided in the buffer region 20, but may be provided above the buffer region 20. The first lifetime control region 151 of this example is provided to extend from the inside of the transistor portion 70 to the end portion of the boundary region 90 in the trench array direction. The first lifetime control region 151 may be provided to extend from the inside of the transistor portion 70 to the inside of the boundary region 90 or the diode portion 80 in the trench array direction.

The second lifetime control region 152 is provided on the back surface 23 side with respect to the front-surface-side lifetime control portion 155 in the diode portion 80. The second lifetime control region 152 may be provided on the back surface 23 side or may be provided on the front surface 21 side with respect to the center of the semiconductor substrate 10 in the depth direction of the semiconductor substrate 10. The second lifetime control region 152 of this example is provided on the back surface 23 side with respect to the center of the semiconductor substrate 10 in the depth direction of the semiconductor substrate 10. The second lifetime control region 152 is provided at a depth different from that of the first lifetime control region 151. The second lifetime control region 152 may be provided on the front surface 21 side with respect to the first lifetime control region 151. The second lifetime control region 152 of this example is provided on the front surface 21 side with respect to the first lifetime control region 151 in the depth direction of the semiconductor substrate 10. The second lifetime control region 152 may be provided on the back surface 23 side with respect to the first lifetime control region 151 in the depth direction of the semiconductor substrate 10. The second lifetime control region 152 may be provided inside the buffer region 20, or may be provided above the buffer region 20. The second lifetime control region 152 of this example is provided inside the buffer region 20. The second lifetime control region 152 of this example is provided to extend from the diode portion 80 to the boundary region 90 in the trench array direction. The second lifetime control region 152 of this example has an extension region 153.

The extension region 153 is a region of the second lifetime control region 152 extending from the boundary 78 between the transistor portion 70 and the diode portion 80 to the inside of the transistor portion 70. The extension region 153 of this example is provided to extend from the boundary 78 between the transistor portion 70 and the diode portion 80 to the boundary 79 at the end portion of the boundary region 90 in the trench array direction. The area of the extension region 153 in the top view may be 30% or less, may be 20% or less, may be 10% or less, may be 5% or less, may be 3% or less, or may be 1% or less of the area of the second lifetime control region 152 in the top view. The number of the mesa portions 91 in the extension region 153 may be 10 or less, may be 5 or less, may be 2 or less, or may be 0. The number of the mesa portions 91 of this example is 1. The number of the mesa portions 92 may be 1 or more. The number of the mesa portions 92 may be larger than or may be equal to the number of the mesa portions 91. The number of the mesa portions 92 of this example is equal to the number of the mesa portions 91. The boundary region 90 may have only the mesa portion 92. The extension region 153 may have only the mesa portion 92.

The back-surface-side lifetime control portion 150 may be formed by implanting impurity ions for forming a lifetime killer from the back surface 23 side. The impurity ions for forming a lifetime killer may simply be referred to as the impurity ions. The impurity ions may be ions of a material constituting the semiconductor substrate 10, or may be ions other than the material constituting the semiconductor substrate 10. The impurity ions may be ions (for example, hydrogen ions and helium ions) having a mass smaller than that of the material constituting the semiconductor substrate, or may be ions having a mass larger than that of the material constituting the semiconductor substrate 10. The impurity ions of this example are helium ions. With this configuration, an influence on the front surface 21 side of the semiconductor device 100 can be avoided. For example, the back-surface-side lifetime control portion 150 is formed by implanting helium ions from the back surface 23 side. Here, whether the back-surface-side lifetime control portion 150 is formed by implantation from the front surface 21 side or formed by implantation from the back surface 23 side can be determined by acquiring the state of the front surface 21 side by an SIMS method, the SRP method, or the measurement of a leakage current. For example, using the SIMS method, if the atomic density distribution spreads from the depth position where the atomic density becomes the maximum value to the back surface 23 side more than the front surface 21 side, it may be considered that impurity ions are implanted from the back surface 23 side.

The forming methods of the back-surface-side lifetime control portion 150 and the front-surface-side lifetime control portion 155 may be the same as each other or different from each other. Both the back-surface-side lifetime control portion 150 and the front-surface-side lifetime control portion 155 may be formed by implanting impurity ions from the back surface 23 side. The front-surface-side lifetime control portion 155 may be formed by implantation of impurity ions from the front surface 21 side, and the back-surface-side lifetime control portion 150 may be formed by implantation of impurity ions from the back surface 23 side. The dose amounts of impurity ions when the back-surface-side lifetime control portion 150 and the front-surface-side lifetime control portion 155 are formed may be the same as each other or may be different from each other.

Here, when a collector-emitter cutoff current (or collector-emitter leakage current) Ices increases, thermal runaway may occur in the semiconductor device. On the other hand, as described below, since there is a trade-off relationship between the collector-emitter cutoff current Ices and the reverse recovery loss, the reverse recovery loss may increase when the collector-emitter cutoff current Ices is to be reduced.

In the semiconductor device 100 of this example, by forming the first lifetime control region 151 formed in the transistor portion 70 to be shallower than the second lifetime control region 152, it is possible to reduce the reverse recovery loss while reducing the leakage current as compared with forming the lifetime killer on the back surface side at the same depth, so that it is possible to improve the trade-off between the leakage current and the reverse recovery loss.

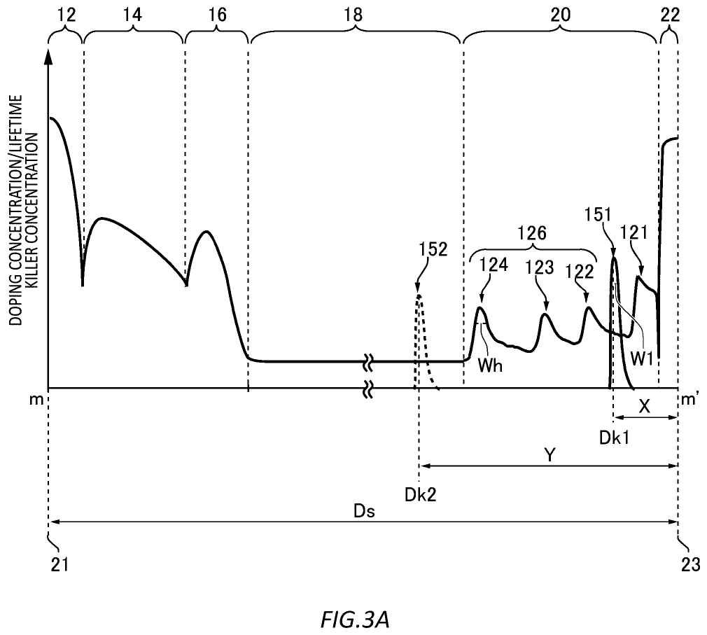

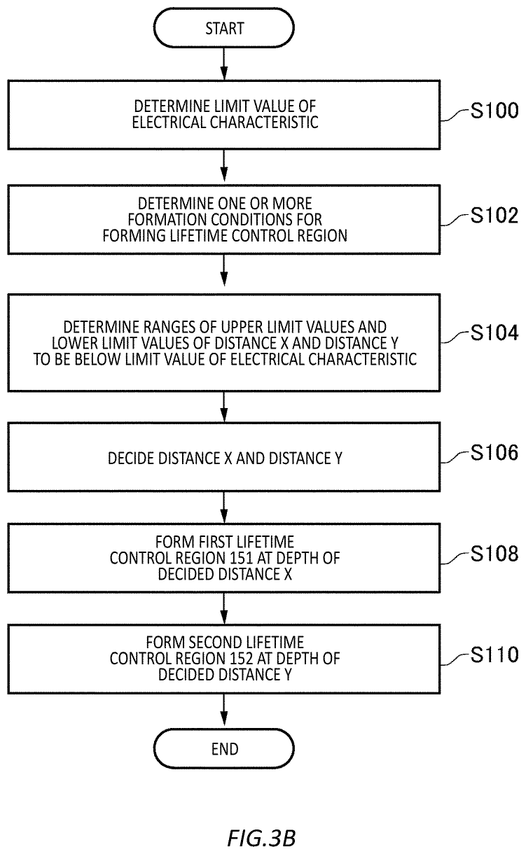

FIG. 3A illustrates a concentration distribution in the depth direction of the semiconductor substrate 10. A vertical axis represents the doping concentration or the lifetime killer concentration. A horizontal axis represents the position of the semiconductor substrate 10 in the depth direction. This figure illustrates the concentration distribution in a m-m′ cross section of FIG. 2B passing through the emitter region 12, the base region 14, the accumulation region 16, the drift region 18, the buffer region 20 and the collector region 22.

The m-m′ cross section passes through the first lifetime control region 151 in the X axis direction but does not pass through the second lifetime control region 152. In this example, in addition to the concentration distribution in the m-m′ cross section, the concentration distribution in the second lifetime control region 152 is illustrated in an overlapping manner by a broken line.

The buffer region 20 has one or more peaks of the doping concentration in the depth direction of the semiconductor substrate 10. The buffer region 20 may be formed by ion implantation of hydrogen and include the hydrogen donor. The buffer region 20 may include the peak of the doping concentration formed by ion implantation of phosphorous. The buffer region 20 of this example has a first peak 121 and a sub peak group 126.

The first peak 121 and the sub peak group 126 may be formed by ion implantation of hydrogen. In this example, the first peak 121 is formed by ion implantation of phosphorous, and the sub peak group 126 is formed by ion implantation of hydrogen.

The sub peak group 126 is provided on the front surface 21 side with respect to the first peak 121 in the depth direction of the semiconductor substrate 10. The sub peak group 126 has one or more peaks of the doping concentration. The sub peak group 126 in this example has three peaks including a second peak 122, a third peak 123, and a fourth peak 124. That is, the buffer region 20 of this example has four peaks of the doping concentration in the depth direction of the semiconductor substrate 10. The buffer region 20 has the peaks in the stated order of a first peak 121, a second peak 122, a third peak 123, and a fourth peak 124 from the back surface 23 in the depth direction of the semiconductor substrate 10. The peak concentration of the sub peak group 126 may gradually decrease toward the front surface 21 side. The peak concentration of the first peak 121 may be higher than any peak concentration of the sub peak group 126.

A distance X (μm) is a distance of the first lifetime control region 151 from the back surface 23 in the depth direction. That is, the distance X may be a depth position Dk1 of the first lifetime control region 151 from the back surface 23. The first lifetime control region 151 may be provided on the front surface 21 side with respect to the first peak 121 in the depth direction of the semiconductor substrate 10. The first lifetime control region 151 of this example is provided between the first peak 121 and the second peak 122 in the depth direction of the semiconductor substrate 10.

The distance X is larger than the distance in the depth direction between the peak of the doping concentration of the collector region 22 and the back surface 23, and may be ¼ or less of a thickness Ds of the semiconductor substrate 10. The distance X may be 0 μm or more, may be 1.0 μm or more, may be 5.0 μm or more, may be 50 μm or less, or may be 30 μm or less. The distance X may be larger than the peak depth of the first peak 121. The distance X may be smaller than the peak depth (the peak depth of the second peak 122 in this example) positioned closest to the back surface 23 side in the sub peak group 126. The distance X may be smaller than the distance from the front surface 21 to the back surface 23 of the semiconductor substrate 10. The distance from the front surface 21 to the back surface 23 of the semiconductor substrate 10 may be the thickness Ds of the semiconductor substrate 10.

A distance Y (μm) is a distance of the second lifetime control region 152 from the back surface 23 in the depth direction. That is, the distance Y may be a depth position Dk2 of the second lifetime control region 152 from the back surface 23. The second lifetime control region 152 may be provided on the front surface 21 side with respect to the buffer region 20 in the depth direction of the semiconductor substrate 10. The distance Y may be smaller than the distance from the front surface 21 to the back surface 23 of the semiconductor substrate 10.

The distance X and the distance Y may satisfy Y>2X. Y/X, which is the ratio of the distance Y to the distance X, may be 1.5 or more, may be 2 or more, may be 3 or more, may be 5 or more, or may be 10 or more. The ratio Y/X may be 100 or less, may be 70 or less, may be 50 or less, may be 30 or less, or may be 20 or less. The distance Y may be 1.5 X or more or may be ½ or less of the thickness Ds of the semiconductor substrate 10.

In the depth direction of the semiconductor substrate 10, the first lifetime control region 151 may be provided on the front surface 21 side with respect to the first peak 121, or may be provided on the back surface 23 side with respect to the first peak 121. The first lifetime control region 151 may not overlap with the first peak 121 in the depth direction of the semiconductor substrate 10. With this configuration, the possibility of formation failure of the first peak 121 due to lattice defects can be reduced, and the depletion layer can be reliably stopped. The first lifetime control region 151 may be provided at any position in the buffer region 20 when the buffer region 20 is composed only of hydrogen peak.

The first lifetime control region 151 may be provided between adjacent peaks in the depth direction of the semiconductor substrate 10 among the respective peaks of the first peak 121 or the sub peak group 126. With this configuration, since the first lifetime control region 151 is positioned in a region where the component of an electric field intensity in the depth direction is relatively small, it is possible to suppress an increase in the leakage current due to the introduction of the first lifetime control region 151.

A width W1 (μm) is the full width at half maximum (FWHM) of the peak of the lifetime killer concentration of the first lifetime control region 151. The width W1 in this example is the full width at half maximum of the distribution of the lifetime killer concentration of the first lifetime control region 151 in the depth direction of the semiconductor substrate 10. The distance X and the distance Y may satisfy Y>X+W1. That is, a difference in the distance in the depth direction between the first lifetime control region 151 and the second lifetime control region 152 may be larger than W1.

A width Wh (μm) is the full width at half maximum of the hydrogen concentration of the hydrogen peak for forming the buffer region 20. The width Wh of this example is the full width at half maximum of the hydrogen concentration distribution of the hydrogen peak in the depth direction of the semiconductor substrate 10. The width Wh in this example is the full width at half maximum of the deepest fourth peak 124, but may be the full width at half maximum of another hydrogen peak. The distance X and the distance Y may satisfy Y>X+Wh. That is, a difference in the distance in the depth direction between the first lifetime control region 151 and the second lifetime control region 152 may be larger than Wh.

FIG. 3B illustrates an example of a flowchart of a manufacturing method of the semiconductor device 100. In this example, an example of the method of manufacturing the semiconductor device 100 by deciding the distance X and the distance Y on the basis of the electrical characteristic of the semiconductor device 100 will be illustrated. The manufacturing method of the semiconductor device 100 is not limited thereto.

In step S100, a limit value of the electrical characteristic of the semiconductor device 100 is determined. The limit value of the electrical characteristic may be a limit value of the current density (nA/mm²) of the collector-emitter cutoff current Ices of the semiconductor device 100. The electrical characteristic may be a characteristic other than the current density of the collector-emitter cutoff current Ices.

In step S102, one or more formation conditions for forming the lifetime control region are determined. For example, one or more formation conditions for forming the first lifetime control region 151 or the second lifetime control region 152 are determined. The formation condition for forming the first lifetime control region 151 or the second lifetime control region 152 may be a condition related to the range of the position of the first lifetime control region 151 or the second lifetime control region 152 in the depth direction of the semiconductor substrate 10.

In step S104, the range of the upper limit value and the lower limit value of each of the distance X and the distance Y is determined by determining one or more relational expressions connecting the distance X and the distance Y for the formation condition determined in step S102 such that the electrical characteristic of the semiconductor device 100 is equal to or less than the limit value determined in step S100.

In step S106, the distance X and the distance Y are decided. The distance X and the distance Y may be arbitrarily decided from the range of the upper limit value and the lower limit value of each of the distance X and the distance Y set in step S104.

In step S108, the first lifetime control region 151 is formed at the depth of the distance X decided in step S106. In step S110, the second lifetime control region 152 is formed at the depth of the distance Y decided in step S106. With this configuration, the semiconductor device 100 including the lifetime control region may be manufactured.

Between step S106 and step S108, there may be a known step of manufacturing the semiconductor device 100. As an example, there may be a step of forming the well region 17, the base region 14, the emitter region 12, the gate trench portion 40, the emitter electrode 52, and the like on the front surface 21, there may be a step of reducing the thickness of the semiconductor substrate 10 in the depth direction, there may be a step of forming the collector region 22 and the like on the back surface 23 of the semiconductor substrate 10, or there may be a step of forming the buffer region 20. After step S110, there may be a known step of manufacturing the semiconductor device 100. As an example, there may be a step of forming the collector electrode 24 on the back surface 23 of the semiconductor substrate 10.

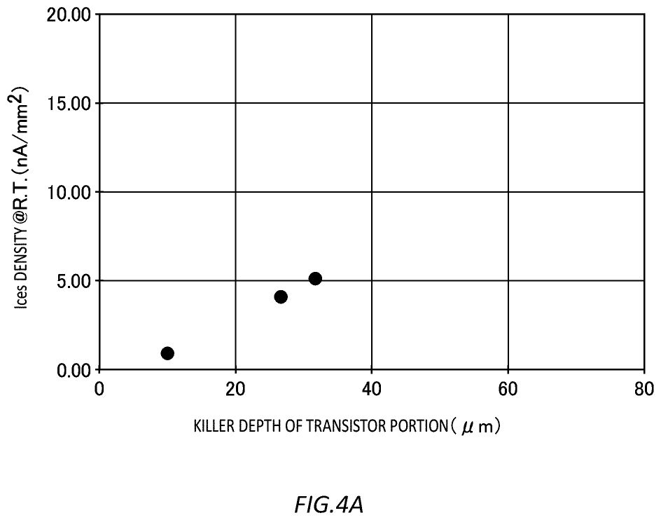

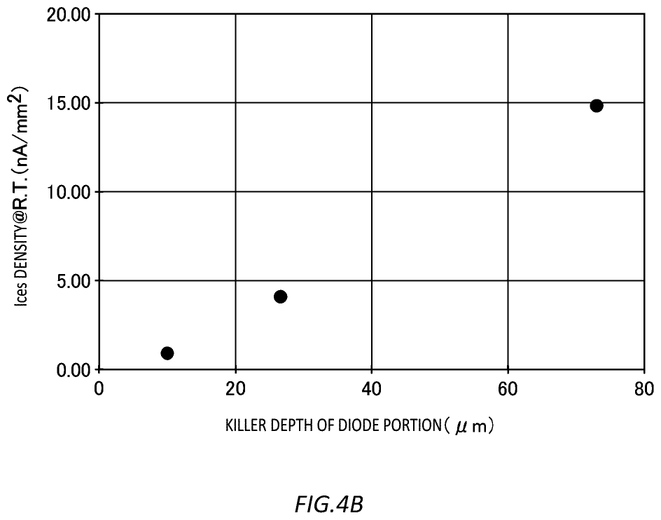

FIG. 4A illustrates a relationship between the depth of the lifetime control region and a leakage current density. A vertical axis represents the current density (nA/mm²) of the collector-emitter cutoff current Ices at room temperature. The room temperature may be 300 K (26.9° C.), or may be a temperature between 20° C. and 30° C. The temperature at which the current density of the collector-emitter cutoff current Ices is acquired is not limited to the room temperature, and may be 400 K (126.9° C.) or may be −30° C. The temperature at which the current density of the collector-emitter cutoff current Ices is acquired may be −30° C. or higher, may be −10° C. or higher, may be 0° C. or higher, or may be 20° C. or higher. The temperature at which the current density of the collector-emitter cutoff current Ices is acquired may be 200° C. or lower, may be 150° C. or lower, may be 125° C. or lower, may be 100° C. or lower, may be 75° C. or lower, may be 50° C. or lower, or may be 30° C. or lower. The collector-emitter cutoff current Ices is a leakage current between the collector and the emitter when a predetermined voltage is applied between the collector and the emitter in a state where the gate and the emitter are short-circuited. A horizontal axis represents the killer depth of the transistor portion from the back surface. The lifetime control region of this example is formed by helium radiation, and the radiation amount is 5E11 cm⁻². As illustrated in this figure, as the position of the lifetime killer in the transistor portion is formed deeper from the back surface, the passed-through region of ions for forming the lifetime killer becomes wider, and radiation is performed with deeper energy, so that the current density of the collector-emitter cutoff current Ices tends to increase.

FIG. 4B illustrates the relationship between the depth of the lifetime control region and the leakage current density. A vertical axis represents the current density (nA/mm²) of the collector-emitter cutoff current Ices at room temperature. A horizontal axis represents the killer depth of the diode portion from the back surface. The lifetime control region of this example is formed by helium radiation, and the radiation amount is 5E11 cm⁻². As illustrated in this figure, as the position of the lifetime killer in the diode portion is formed deeper from the back surface, the current density of the collector-emitter cutoff current Ices tends to increase.

From FIGS. 4A and 4B, it can be seen that in both the transistor portion and the diode portion, the position of the lifetime killer is formed to be deep from the back surface, so that the leakage current increases. In addition, it can be seen that in both the transistor portion and the diode portion, the leakage current density increases to the same extent with respect to the depth of the lifetime control region.

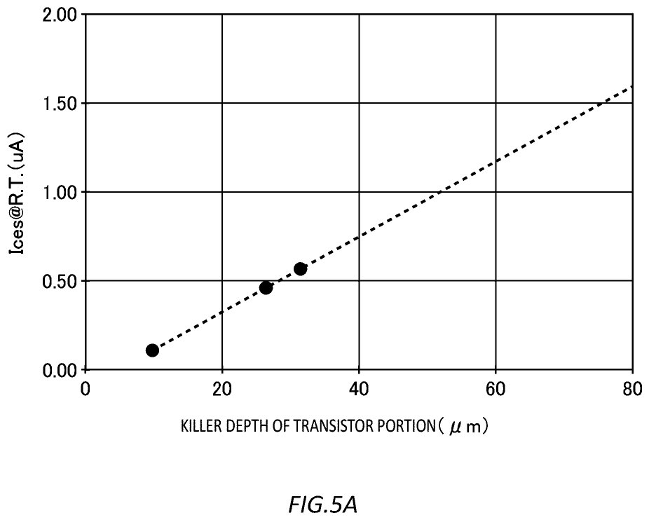

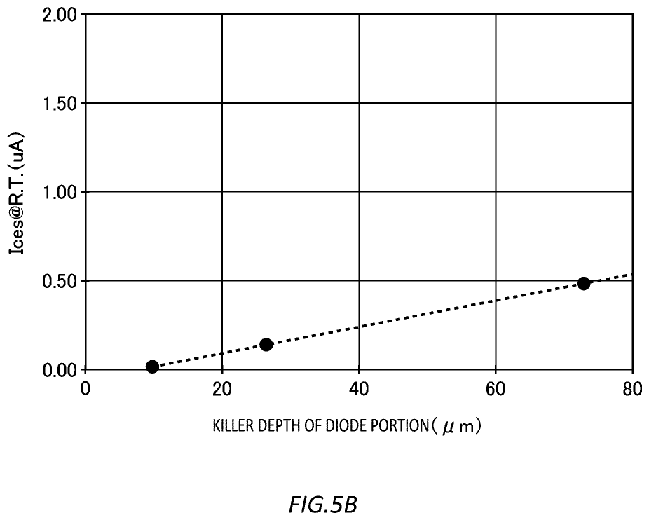

FIG. 5A illustrates a relationship between the depth of the lifetime control region and the leakage current. A vertical axis represents the collector-emitter cutoff current Ices (μA) at room temperature. A horizontal axis represents the killer depth of the transistor portion from the back surface. The area of the transistor portion of this example is 110 mm². The lifetime control region of this example is formed by helium radiation, and the radiation amount is 5E11 cm⁻². Similarly to FIG. 4A, as the position of the lifetime killer in the transistor portion is formed deeper from the back surface, the collector-emitter cutoff current Ices tends to increase.

FIG. 5B illustrates the relationship between the depth of the lifetime control region and the leakage current. A vertical axis represents the collector-emitter cutoff current Ices (μA) at room temperature. A horizontal axis represents the killer depth of the diode portion from the back surface. The area of the diode portion of this example is 30 mm². The lifetime control region of this example is formed by helium radiation, and the radiation amount is 5E11 cm⁻². Similarly to FIG. 4B, as the position of the lifetime killer in the diode portion is formed deeper from the back surface, the collector-emitter cutoff current Ices tends to increase.

Here, the collector-emitter cutoff current Ices of the entire semiconductor device can be calculated by summing the collector-emitter cutoff current Ices of the transistor portion in FIG. 5A and the collector-emitter cutoff current Ices of the diode portion in FIG. 5B. Referring to FIGS. 5A and 5B, since the area of the transistor portion is larger than the area of the diode portion, it can be seen that the collector-emitter cutoff current Ices of the transistor portion is larger than the collector-emitter cutoff current Ices of the diode portion.

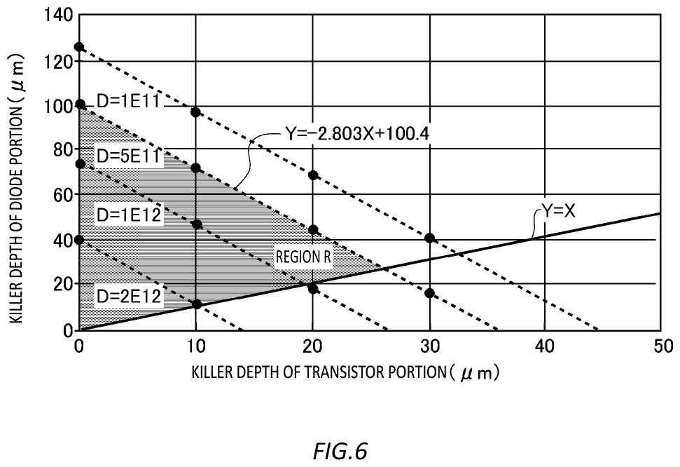

FIG. 6 illustrates a diagram for describing a conditional expression of the depth of the lifetime control region. A vertical axis illustrates the killer depth of the diode portion 80 from the back surface 23, and a horizontal axis illustrates the killer depth of the transistor portion 70 from the back surface 23. In the semiconductor device 100, the killer depth of the transistor portion 70 from the back surface 23 corresponds to the distance X, and the killer depth of the diode portion 80 from the back surface 23 corresponds to the distance Y.

A region R indicates a range to be satisfied by the distance X (μm) and the distance Y (μm). The distance X (μm) may be larger than 0 μm, may be 0.1 μm or more, or may be 1 μm or more. The distance X (μm) may be smaller than the distance from the front surface 21 to the back surface 23 of the semiconductor substrate 10, or may be smaller than the distance from the bottom portion of the trench portion to the back surface 23. The distance Y (μm) may be larger than 0, may be 0.1 μm or more, or may be 1 μm or more. The distance Y (μm) may be smaller than the distance from the front surface 21 to the back surface 23 of the semiconductor substrate 10, or may be smaller than the distance from the bottom portion of the trench portion to the back surface 23. The range of the region R also varies with the lifetime killer concentration of the lifetime control region in addition to the distance X and the distance Y. As an example, when the lifetime killer concentration is 5×10¹¹ atoms/cm², and a ratio I of the active area of the transistor portion 70 to an area S of the active portion 160 is 0.77, the region R corresponds to a region enclosed by an equation Y=X, an equation Y=−2.803X+100.4, and X=0. Here, the units for both of the values of X and Y are (μm). Within the range of the region R, the distance X and the distance Y may be decided such that the semiconductor device 100 satisfies a predetermined characteristic. Here, the region R is decided such that the maximum value of the current density (nA/mm²) of the collector-emitter cutoff current Ices becomes 4.14 nA/mm² at room temperature, but the present invention is not limited thereto. As the predetermined characteristic, the maximum value of the current density (nA/mm²) of the collector-emitter cutoff current Ices may be 0.3 nA/mm² or more, may be 1.0 nA/mm² or more, or may be 3.0 nA/mm² or more at room temperature. As the predetermined characteristic, the maximum value of the current density (nA/mm²) of the collector-emitter cutoff current Ices may be 15.0 nA/mm² or less, may be 10.0 nA/mm² or less, or may be 5.0 nA/mm² or less at room temperature.

A symbol D (atoms/cm²) is a dose amount for forming the second lifetime control region 152. Since a dose amount D can be calculated by integrating the lifetime killer concentration, the dose amount D can be calculated by analyzing the lifetime killer concentration of the second lifetime control region 152 formed in the semiconductor substrate 10. In determining the range of the region R, the dose amount D is, as an example, a dose amount of helium ions, but is not limited thereto. The dose amount D may be based on hydrogen ions or may be based on electron beams. In determining the range of the region R, the dose amount D is, as an example, 1×10¹¹ atoms/cm², but is not limited thereto. The dose amount D may be 1×10¹⁰ atoms/cm² or more, may be 3×10¹⁰ atoms/cm² or more, may be 5×10¹⁰ atoms/cm² or more, or may be 1×10¹¹ atoms/cm² or more. In determining the range of the region R, the dose amount D may be 3×10¹² atoms/cm² or less, may be 1×10¹² atoms/cm² or less, may be 5×10¹¹ atoms/cm² or less, or may be 3×10¹¹ atoms/cm² or less. As the dose amount D is increased, the range to be satisfied by the distance X and the distance Y is narrowed. That is, by changing the dose amount D, the intercept changes so that the straight line moves up or down with the slope of Y=−2.803X+100.4 remaining constant. By deciding the distance X and the distance Y in the region R below this straight line, the semiconductor device 100 satisfying the predetermined characteristic can be provided.

Here, the distance X (μm) and the distance Y (μm) may satisfy (Mathematical formula 1) and (Mathematical formula 2) by introducing a parameter B decided according to the structure of the semiconductor device 100. (Mathematical formula 1) is a conditional expression for forming the second lifetime control region 152 deeper from the back surface 23 than the first lifetime control region 151. (Mathematical formula 2) is a conditional expression using the dose amount D, for preventing thermal runaway of the semiconductor device 100 due to heat generation by the collector-emitter cutoff current Ices.

$$\\ \begin{matrix}Y > X & ( Mathematical formula 1 )\end{matrix}$$

$$\\ \begin{matrix}Y \leq BX - 27 B + 1.18 \times {10}^{{}_{} - 23} {D}^{{}_{} 2} - 7.02 \times {10}^{{}_{} - 11} D + 56.89 & ( Mathematical formula 2 )\end{matrix}$$

The parameter B satisfies (Mathematical Formula 3) using the ratio I of the active area of the transistor portion 70 to the area S of the active portion 160. The parameter B is a dimensionless number. By using the parameter B, it is possible to reflect the influence of the ratio I of the active area of the transistor portion 70 to the area S of the active portion 160.

$$\\ \begin{matrix}B = - 0.139 {e}^{{}_{} 3.9 \vert} & ( Mathematical formula 3 )\end{matrix}$$

As described above, by using (Mathematical formula 2), the influence of the area S of the active portion 160 and the influence of the ratio I of the active areas of the transistor portion 70 and the diode portion 80 can be reflected on the conditional expression of the distance X and the distance Y in consideration of the influence of the dose amount D. A method of calculating the parameter B will be described below.

The active portion 160 may be a region which is enclosed by the well region 17 in the top view and in which a main current flows in the depth direction between the front surface 21 and the back surface 23 of the semiconductor substrate 10 during the operation of the semiconductor device 100. The area S of the active portion 160 may be the sum of the total value of the areas of one or more transistor portions 70 and the total value of the areas of one or more diode portions 80. The area S of the active portion 160 may be 3 mm² or more, may be 10 mm² or more, may be 30 mm² or more, or may be 100 mm² or more. The area S of the active portion 160 may be 3000 mm² or less, may be 1000 mm² or less, may be 500 mm² or less, or may be 300 mm² or less.

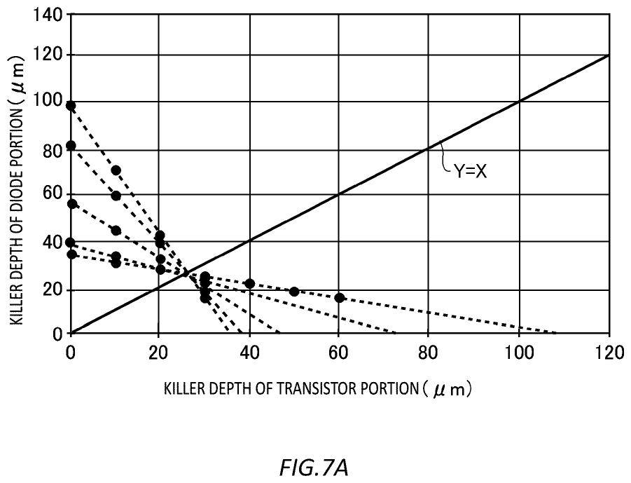

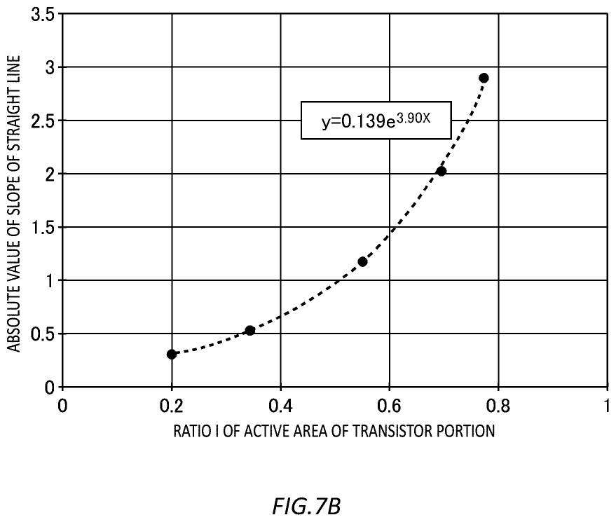

FIG. 7A illustrates a diagram for describing a method of calculating the parameter B. A vertical axis illustrates the killer depth of the diode portion, and a horizontal axis illustrates the killer depth of the transistor portion. In this example, the area of the active portion of the semiconductor device is fixed. In this case, since the proportion of the collector-emitter cutoff current Ices changes according to the change in the ratio I of the active area of the transistor portion to the area of the active portion, the relational expression of the killer depth changes according to the ratio I of the active area of the transistor portion to the area of the active portion. In this example, as an example, a relational expression of XY when the ratio I of the active area between the transistor portion and the diode portion is changed to each of 0.2, 0.35, 0.55, 0.7, and 0.77 is shown. By changing the ratio I of the active area of the transistor portion to the area of the active portion, a graph changes so that the slope changes around the point at which the killer depth of the transistor portion and the killer depth of the diode portion become the same. The ratio I of the active area of the transistor portion to the area of the active portion in the calculation of the parameter B may be 0.1 or more, may be 0.2 or more, may be 0.35 or more, may be 0.5 or more, or may be 0.55 or more. The ratio I of the active area of the transistor portion to the area of the active portion in the calculation of the parameter B may be 0.9 or less, may be 0.8 or less, may be 0.77 or less, or may be 0.7 or less.

FIG. 7B illustrates a diagram for describing the method of calculating the parameter B. This figure is a diagram in which a change in slope according to the ratio I of the active area of the transistor portion to the area of the active portion in FIG. 7A is plotted for each ratio I of the active area of the transistor portion to the area of the active portion. A vertical axis represents the absolute value of the slope of the straight line in FIG. 7A, and a horizontal axis represents the ratio I of the active area of the transistor portion to the area of the active portion. From this figure, (Mathematical formula 4) can be calculated. In this way, the influence of the ratio I of the active area of the transistor portion to the area of the active portion can be reflected on the limit line of the killer depth. That is, the slope of the leakage current limit can be calculated from the ratio I of the active area of the transistor portion to the area of the active portion.

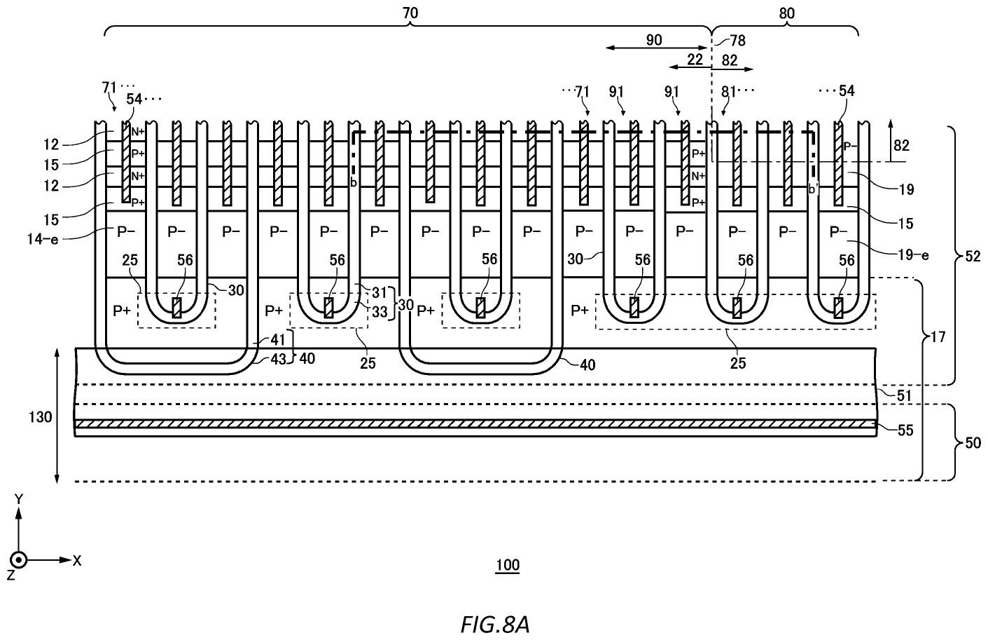

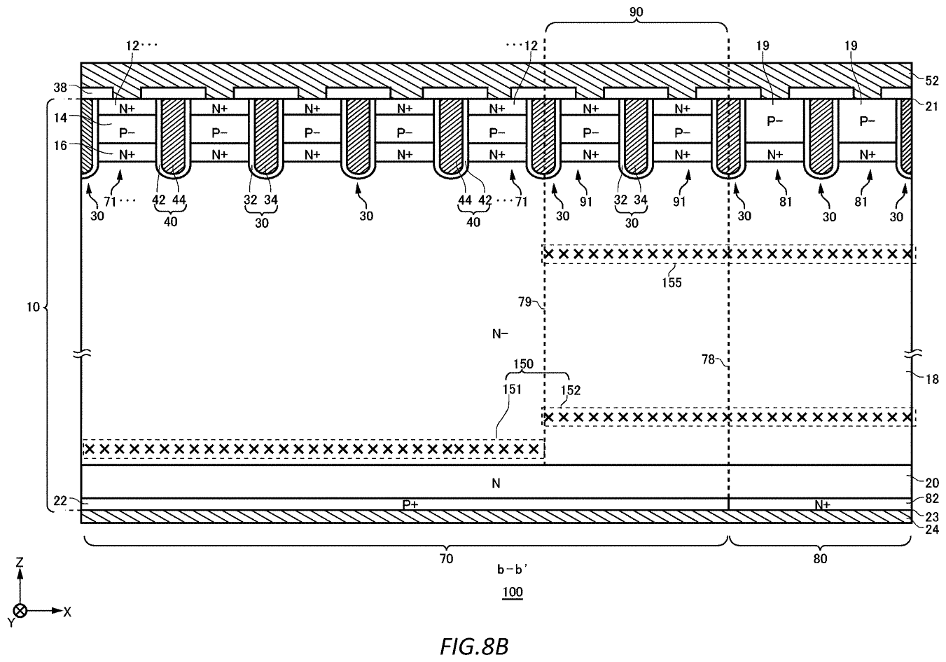

FIG. 8A illustrates a top view of a modification of the semiconductor device 100. In this example, points different from the semiconductor device 100 of FIG. 2A will be particularly described.

The emitter region 12 of this example is also provided in the boundary region 90. The emitter region 12 and the contact region 15 may be provided in the mesa portion 91 similarly to the mesa portion 71. That is, the emitter regions 12 may be provided alternately with the contact regions 15 also in the mesa portion 91. An interval between the emitter region 12 and the contact region 15 may be the same between the mesa portion 71 and the mesa portion 91. The emitter region 12 and the contact region 15 of the mesa portion 91 may be arranged so as to face the emitter region 12 and the contact region 15 of the mesa portion 71 with the trench portion interposed therebetween.

FIG. 8B illustrates a view showing an example of an XZ cross section including a b-b′ cross section in FIG. 8A. The XZ cross section including the b-b′ cross section is an XZ plane that passes through the emitter region 12 in the transistor portion 70. In this example, points different from the semiconductor device 100 in FIG. 2B will be particularly described.

The first lifetime control region 151 is provided to extend from below the mesa portion 71 to the boundary 79 in the trench array direction. The first lifetime control region 151 may be provided to extend from below the mesa portion 71 to below the mesa portion 91 beyond the boundary 79 in the trench array direction. The first lifetime control region 151 of this example is provided above the buffer region 20. That is, in this example, both the first lifetime control region 151 and the second lifetime control region 152 are provided above the buffer region 20.

The second lifetime control region 152 is provided to extend from the diode portion 80 to the transistor portion 70 in the trench array direction. The second lifetime control region 152 of this example is provided to extend from the diode portion 80 to a region below the emitter region 12 provided in the boundary region 90 in the trench array direction. The second lifetime control region 152 of this example is provided to extend from the diode portion 80 to the boundary 79 in the trench array direction. The second lifetime control region 152 may extend from the diode portion 80 to the inside of the boundary region 90 in the trench array direction and terminate without reaching the boundary 79.

The boundary of the first lifetime control region 151 and the second lifetime control region 152 in the trench array direction matches the boundary 79. The boundary of the first lifetime control region 151 and the second lifetime control region 152 in the trench array direction may be between the boundary 78 and the boundary 79 or may match the boundary 78.

The front-surface-side lifetime control portion 155 is provided to extend from the diode portion 80 to the transistor portion 70 in the trench array direction. The front-surface-side lifetime control portion 155 of this example is provided to extend from the diode portion 80 to a region below the emitter region 12 provided in the boundary region 90 in the trench array direction. The front-surface-side lifetime control portion 155 of this example is provided to extend from the diode portion 80 to the boundary 79 in the trench array direction. That is, the front-surface-side lifetime control portion 155 of this example is provided in the same region as the second lifetime control region 152 in the trench array direction. The front-surface-side lifetime control portion 155 may extend from the diode portion 80 to the inside of the boundary region 90 in the trench array direction and terminate without reaching the boundary 79.

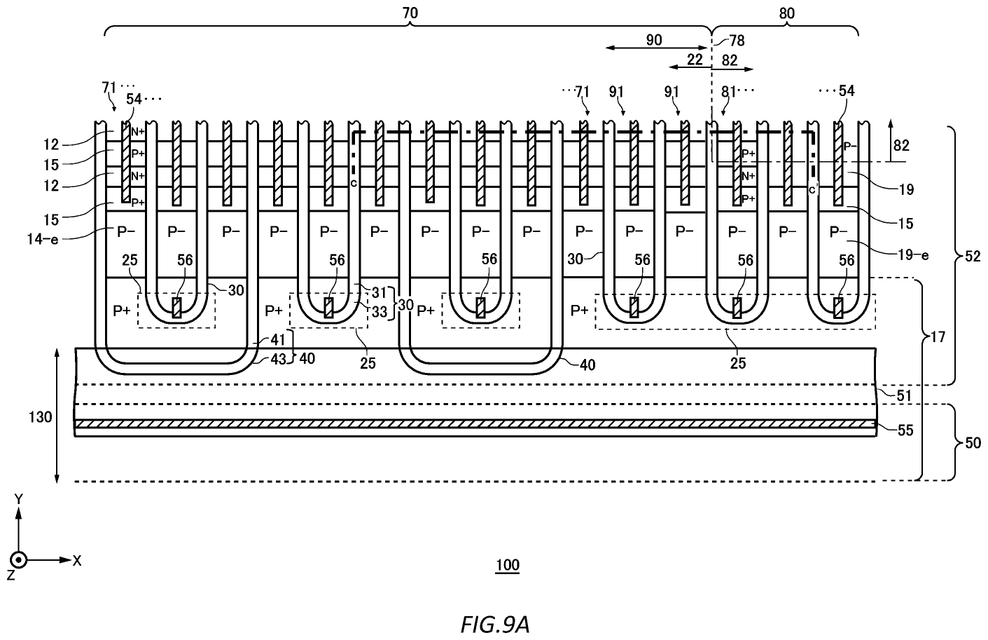

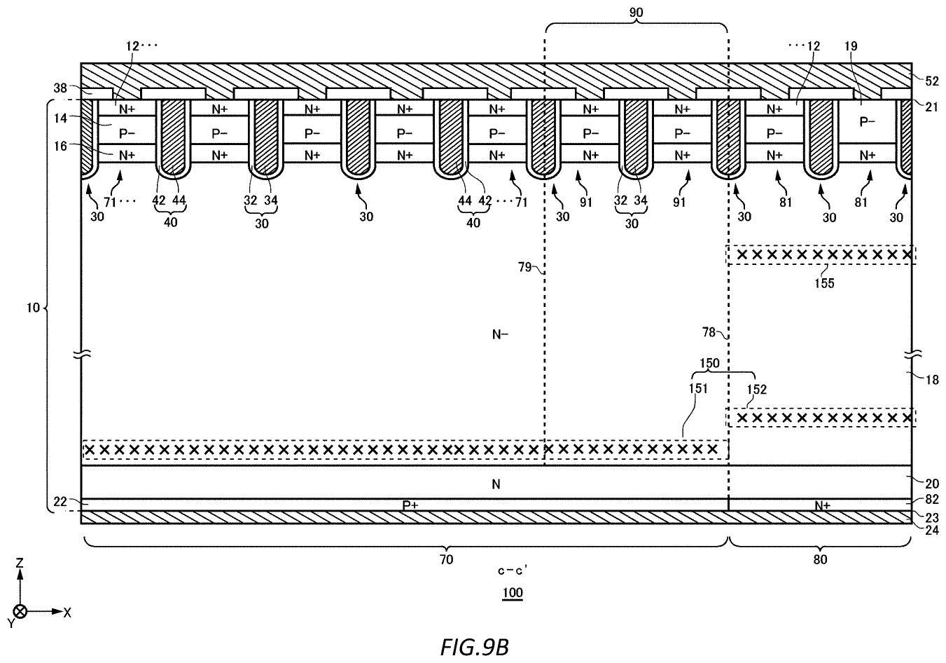

FIG. 9A illustrates a top view of a modification of the semiconductor device 100. In this example, points different from the semiconductor device 100 of FIG. 2A will be particularly described.

The emitter region 12 of this example is also provided in the diode portion 80. The emitter region 12 may also be provided in the boundary region 90. The diode portion 80 may have both the mesa portion 81 provided with the emitter region 12 and the mesa portion 81 not provided with the emitter region 12.

The emitter region 12 and the contact region 15 may be provided in the mesa portion 81 similarly to the mesa portion 71. That is, the emitter regions 12 may be provided alternately with the contact regions 15 also in the mesa portion 81. The interval between the emitter region 12 and the contact region 15 may be the same between the mesa portion 71 and the mesa portion 81. The emitter region 12 and the contact region 15 of the mesa portion 81 may be arranged so as to face the emitter region 12 and the contact region 15 of the mesa portion 71 with the trench portion interposed therebetween.

FIG. 9B illustrates a view showing an example of an XZ cross section including a c-c′ cross section in FIG. 9A. The XZ cross section including the c-c′ cross section is an XZ plane that passes through the emitter region 12 in the transistor portion 70. In this example, points different from the semiconductor device 100 in FIG. 2B will be particularly described.

The first lifetime control region 151 is provided to extend from below the mesa portion 71 to the boundary 78 in the trench array direction. The first lifetime control region 151 may extend beyond the boundary 79 from below the mesa portion 71 in the trench array direction and terminate without reaching the boundary 78. The first lifetime control region 151 of this example is provided below the emitter region 12 of the boundary region 90.

The second lifetime control region 152 is provided to extend from the inside of the diode portion 80 to the boundary 78 in the trench array direction. The second lifetime control region 152 of this example is provided to extend from below the mesa portion 81, which is not provided with the emitter region 12, to below the mesa portion 81, which is provided with the emitter region 12, in the trench array direction. The second lifetime control region 152 may be provided to extend from the boundary 78 of the diode portion 80 on the positive side in the X axis direction to the boundary 78 of the diode portion 80 on the negative side in the X axis direction in the trench array direction. The second lifetime control region 152 may terminate without reaching the boundary 78 from the inside of the diode portion 80 in the trench array direction.

The boundary of the first lifetime control region 151 and the second lifetime control region 152 in the trench array direction matches the boundary 78. The boundary of the first lifetime control region 151 and the second lifetime control region 152 in the trench array direction may be between the boundary 78 and the boundary 79 or may match the boundary 79.

The front-surface-side lifetime control portion 155 is provided to extend from the inside of the diode portion 80 to the boundary 78 in the trench array direction. That is, the front-surface-side lifetime control portion 155 of this example is provided in the same region as the second lifetime control region 152 in the trench array direction. The front-surface-side lifetime control portion 155 of this example is provided to extend from below the mesa portion 81, which is not provided with the emitter region 12, to below the mesa portion 81, which is provided with the emitter region 12, in the trench array direction. In the trench array direction, the front-surface-side lifetime control portion 155 may terminate without reaching the boundary 78 from the inside of the diode portion 80, or may extend from the inside of the diode portion 80 to the boundary region 90 beyond the boundary 78.

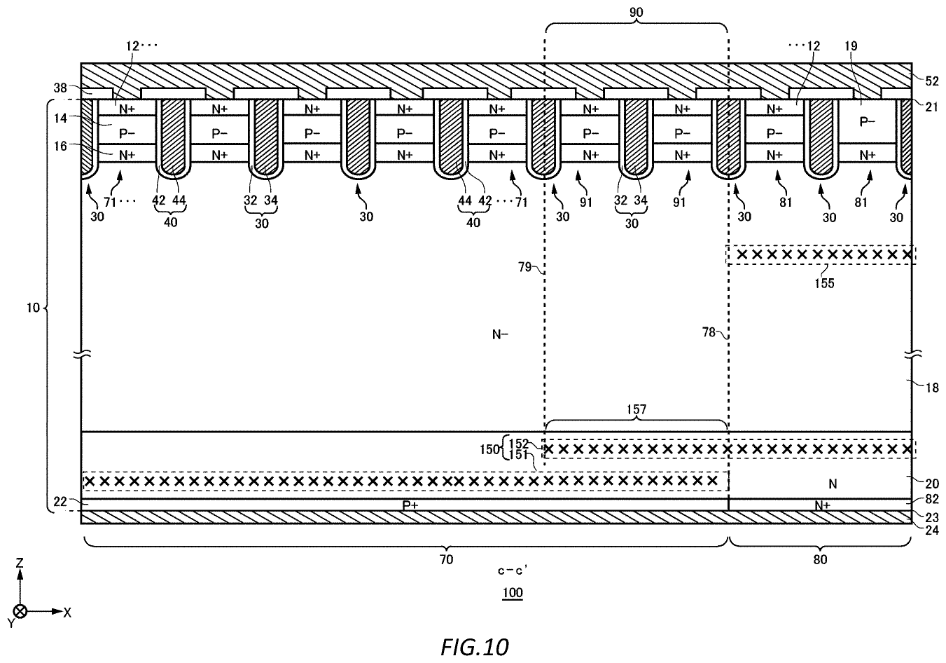

FIG. 10 illustrates a view showing a modification of the XZ cross section including the c-c′ cross section in FIG. 9A. The XZ cross section including the c-c′ cross section is an XZ plane that passes through the emitter region 12 in the transistor portion 70. In this example, points different from the semiconductor device 100 in FIG. 9B will be particularly described. The semiconductor device 100 of this example is different from the semiconductor device 100 of FIG. 9B in including an overlapping region 157.

The overlapping region 157 is a region where the first lifetime control region 151 and the second lifetime control region 152 overlap in the top view. The overlapping region 157 in this example matches the boundary region 90. That is, the first lifetime control region 151 and the second lifetime control region 152 are provided to extend from the boundary 79 to the boundary 78 in the trench array direction. The overlapping region 157 may be provided in any example.

The back-surface-side lifetime control portion 150 may be provided in the buffer region 20. In this example, both the first lifetime control region 151 and the second lifetime control region 152 are provided in the buffer region 20. As described above, the second lifetime control region 152 of this example is provided in the buffer region 20, but may be provided on the front surface 21 side with respect to the buffer region 20 in the depth direction of the semiconductor substrate 10. In any example, both the first lifetime control region 151 and the second lifetime control region 152 may be provided in the buffer region 20, or the first lifetime control region 151 may be provided in the buffer region 20 and the second lifetime control region 152 may be provided outside the buffer region 20.

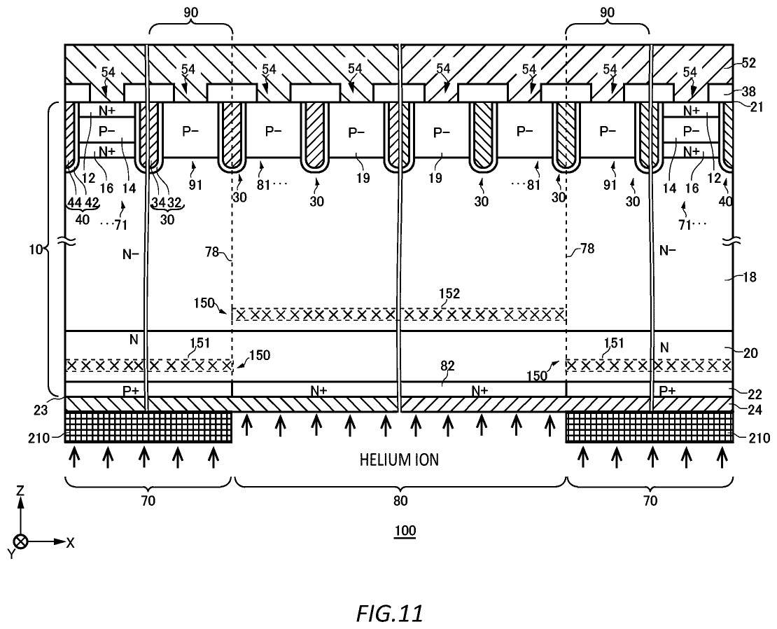

FIG. 11 illustrates an example of a helium ion implantation process using a mask 210. In this example, the first lifetime control region 151 and the second lifetime control region 152 are formed using the mask 210.

The mask 210 is formed on the front surface 21 or the back surface 23 of the semiconductor substrate 10 to form a lifetime killer. The mask 210 of this example is provided on the back surface 23 side, and adjusts the implantation amount of helium ions into the semiconductor substrate 10. The mask 210 may be a resist.

Helium ions are implanted into the entire surface of the back surface 23 in a state where the mask 210 is selectively provided on the back surface 23, so that the back-surface-side lifetime control portions 150 having different depths can be formed. The mask 210 of this example is formed so as to cover the entire surface of the transistor portion 70, and is formed so as not to cover the entire surface of the diode portion 80. However, the mask 210 may be formed so as not to cover a part of the transistor portion 70, or may be formed so as to cover a part of the diode portion 80.

The first lifetime control region 151 is formed in a region where the mask 210 is formed. The first lifetime control region 151 is formed shallower than the second lifetime control region 152 by implanting helium ions through the mask 210. In this example, the first lifetime control region 151 shallower than the second lifetime control region 152 can be formed by reducing the thickness of the mask 210. The thickness of the mask 210 may be 15 μm or less, may be 30 μm or less, or may be 60 μm or less.

The second lifetime control region 152 is formed in an opening portion where the mask 210 is not formed. The second lifetime control region 152 is formed deeper than the first lifetime control region 151 by implanting helium ions without passing through the mask 210.

The back-surface-side lifetime control portion 150 of this example is formed by irradiating the lifetime killer on both the region where the mask 210 is formed and the region where the mask 210 is not formed. That is, the first lifetime control region 151 and the second lifetime control region 152 can be formed by one ion implantation through the mask 210 covering the back surface 23 with a predetermined pattern. With this configuration, the back-surface-side lifetime control portions 150 having different depths can be formed without providing the mask 210 a plurality of times.

When the semiconductor device 100 includes the overlapping region 157, the first lifetime control region 151 and the second lifetime control region 152 may be formed twice by using the mask 210 having a film thickness which allows the implantation of helium ions to be suppressed sufficiently.

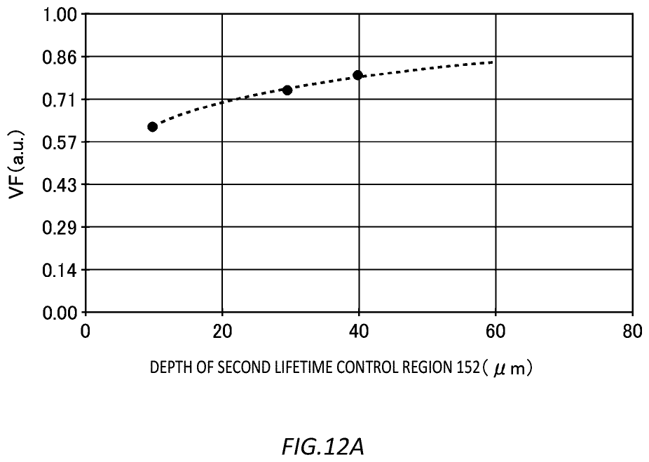

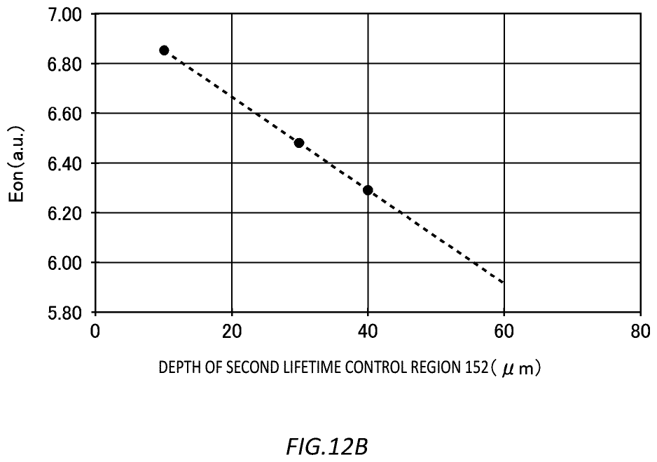

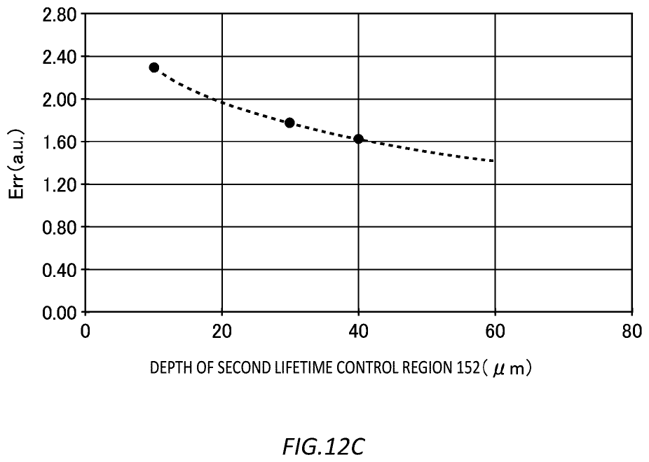

FIG. 12A illustrates dependency of a forward voltage VF on the depth of the second lifetime control region 152. A vertical axis represents the forward voltage VF (a.u.), and a horizontal axis represents the depth (μm) of the second lifetime control region 152. (a.u.) is an arbitrary unit. As an example, an arbitrary value is set as a reference, and a magnification from the arbitrary value is shown. The forward voltage VF of the diode portion 80 changes according to the depth of the second lifetime control region 152. The forward voltage VF increases as the second lifetime control region 152 becomes deeper.

FIG. 12B illustrates dependency of a turn-on loss Eon on the depth of the second lifetime control region 152. A vertical axis represents the turn-on loss Eon (a.u.), and a horizontal axis represents the depth (μm) of the second lifetime control region 152. The turn-on loss Eon also changes according to the depth of the second lifetime control region 152. The turn-on loss Eon decreases as the second lifetime control region 152 becomes deeper.

FIG. 12C illustrates dependency of a switching loss Err during the reverse recovery on the depth of the second lifetime control region 152. A vertical axis represents the switching loss Err (a.u.) during the reverse recovery, and a horizontal axis represents the depth (μm) of the second lifetime control region 152. The switching loss Err during the reverse recovery also changes according to the depth of the second lifetime control region 152. The switching loss Err during the reverse recovery also decreases as the second lifetime control region 152 becomes deeper.

As described above, the forward voltage VF, the turn-on loss Eon, and the switching loss Err during the reverse recovery change according to the depth of the second lifetime control region 152. There is a trade-off relationship between the forward voltage VF and the turn-on loss Eon and between the forward voltage VF and the switching loss Err during the reverse recovery.

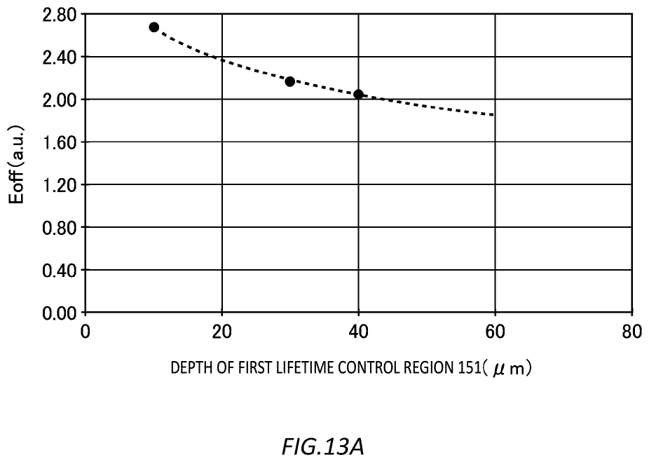

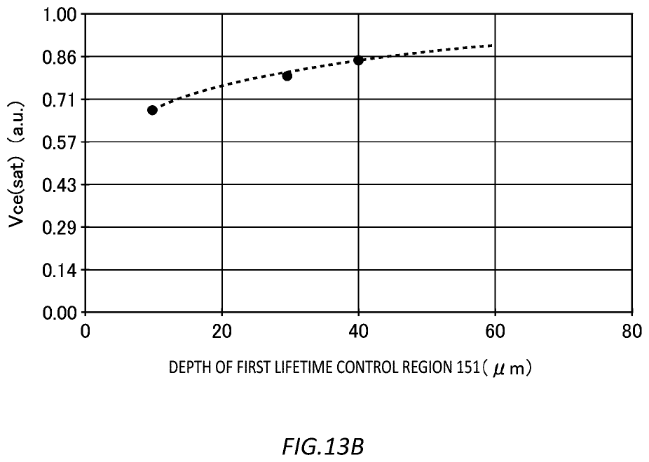

FIG. 13A illustrates dependency of the turn-off loss Eoff on the depth of the first lifetime control region 151. A vertical axis represents the turn-off loss Eoff (a.u.), and a horizontal axis represents the depth (μm) of the first lifetime control region 151. The turn-off loss Eoff changes according to the depth of the first lifetime control region 151. The turn-off loss Eoff decreases as the first lifetime control region 151 becomes deeper.

FIG. 13B illustrates dependency of a collector-emitter saturation voltage Vce (sat) on the depth of the first lifetime control region 151. A vertical axis represents the collector-emitter saturation voltage Vce (sat) (a.u.), and a horizontal axis represents the depth (μm) of the first lifetime control region 151. The collector-emitter saturation voltage Vce (sat) changes according to the depth of the first lifetime control region 151. The collector-emitter saturation voltage Vce (sat) increases as the first lifetime control region 151 becomes deeper.

As described above, the turn-off loss Eoff and the collector-emitter saturation voltage Vce (sat) change according to the depth of the first lifetime control region 151. There is a trade-off relationship between the turn-off loss Eoff and the collector-emitter saturation voltage Vce (sat).

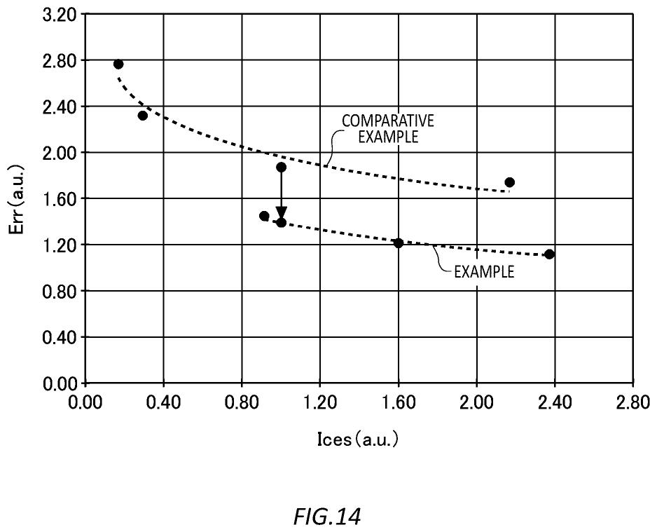

FIG. 14 illustrates an example of improving a trade-off relationship of characteristics of the semiconductor device 100. A vertical axis represents the switching loss Err (a.u.) during the reverse recovery, and a horizontal axis represents the collector-emitter cutoff current Ices (a.u.) at 150° C. This figure illustrates a trade-off relationship between the switching loss Err during the reverse recovery and the collector-emitter cutoff current Ices.

A comparative example is an example in which the lifetime killer on the back surface side of the transistor portion and the lifetime killer on the back surface side of the diode portion are provided at the same depth. On the other hand, in the example, the first lifetime control region 151 and the second lifetime control region 152 have different depths.

In the semiconductor device 100 according to the example, improvement can be obtained by changing the depths of the first lifetime control region 151 and the second lifetime control region 152 to push down a trade-off curve between the switching loss Err during the reverse recovery and the collector-emitter cutoff current Ices by about 30% as compared with the comparative example. As an example, when the switching loss Err during the reverse recovery is about 1.6 (a.u.), the semiconductor device 100 of the example can reduce the collector-emitter cutoff current Ices by about 60% as compared with the comparative example. In one example, by setting the distance X of the first lifetime control region 151 in the depth direction to 10 μm and setting the distance Y of the second lifetime control region 152 in the depth direction to 95 μm, an improvement of about 26% can be obtained as compared with a case where the lifetime killer is uniformly formed at the depth position of 10 μm from the back surface of the semiconductor device substrate.

In the semiconductor device 100 of this example, the trade-off characteristic of the semiconductor device 100 can be improved by setting the depth positions of the first lifetime control region 151 and the second lifetime control region 152 to an appropriate combination. In the semiconductor device 100 of this example, the trade-off characteristic between the electrical loss at the time of switching and the cutoff current (leakage current) can be improved to suppress thermal runaway of the semiconductor device and reduce an electrical loss at the time of switching.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the description of the claims that the embodiments to which such alterations or improvements are made can be included in the technical scope of the present invention.

The operations, procedures, steps, and stages of each process performed by a device, system, program, and method shown in the claims, specification, or drawings can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 19: anode region; 20: buffer region; 21: front surface; 22: collector region; 23: back surface; 24: collector electrode; 25: connection portion; 30: dummy trench portion; 31: extending portion; 32: dummy dielectric film; 33: connecting portion; 34: dummy conductive portion; 38: interlayer dielectric film; 40: gate trench portion; 41: extending portion; 42: gate dielectric film; 43: connecting portion; 44: gate conductive portion; 50: gate metal layer; 51: gate runner portion; 52: emitter electrode; 54: contact hole; 55: contact hole; 56: contact hole; 70: transistor portion; 71: mesa portion; 78: boundary; 79: boundary; 80: diode portion; 81: mesa portion; 82: cathode region; 90: boundary region; 91: mesa portion; 92: mesa portion; 100: semiconductor device; 102: end side; 112: gate pad; 121: first peak; 122: second peak; 123: third peak; 124: fourth peak; 126: sub peak group; 130: gate runner; 150: back-surface-side lifetime control portion; 151: first lifetime control region; 152: second lifetime control region; 153: extension region; 155: front-surface-side lifetime control portion; 157: overlapping region; 160: active portion; 170: edge termination structure portion; and 210: mask.

What is claimed is:

1. A semiconductor device which includes a transistor portion and a diode portion, comprising:
a drift region of a first conductivity type which is provided in a semiconductor substrate;
a plurality of trench portions which are provided on a front surface of the semiconductor substrate;
a buffer region of the first conductivity type which is provided on a side of a back surface of the semiconductor substrate with respect to the drift region;
a first lifetime control region which is provided in the transistor portion; and
a second lifetime control region which is provided at a depth different from that of the first lifetime control region in the diode portion, wherein
when a distance of the first lifetime control region from the back surface in a depth direction is defined as X (μm),
a distance of the second lifetime control region from the back surface in the depth direction is defined as Y (μm), and
a dose amount for forming the second lifetime control region is defined as D (atoms/cm²),
the distance X and the distance Y satisfy (Mathematical Formula 1) and (Mathematical Formula 2)
$$\\ \begin{matrix}Y > X & ( Mathematical formula 1 )\end{matrix}$$
$$\\ \begin{matrix}Y \leq BX - 27 B + 1.18 \times {10}^{{}_{} - 23} {D}^{{}_{} 2} - 7.02 \times {10}^{{}_{} - 11} D + 56.89 , & ( Mathematical formula 2 )\end{matrix}$$
B satisfies (Mathematical Formula 3) using a ratio I of an active area of the transistor portion to an area of an active portion of the semiconductor device
$$\\ \begin{matrix}B = - 0.139 {e}^{{}_{} 3.9 \vert} . & ( Mathematical formula 3 )\end{matrix}$$

2. The semiconductor device according to claim 1, wherein
the first lifetime control region and the second lifetime control region do not overlap with each other in a top view.

3. The semiconductor device according to claim 1, wherein
the first lifetime control region has an overlapping region overlapping with the second lifetime control region in a top view.

4. The semiconductor device according to claim 1, wherein
when a full width at half maximum of a peak of a lifetime killer concentration of the first lifetime control region is defined as W1, Y>X+W1 is satisfied.

5. The semiconductor device according to claim 1, wherein
when a full width at half maximum of a hydrogen concentration of a hydrogen peak for forming the buffer region is defined as Wh, Y>X+Wh is satisfied.

6. The semiconductor device according to claim 1, wherein
the distance X and the distance Y satisfy Y>2X.

7. The semiconductor device according to claim 1, wherein
Y/X, which is a ratio of the distance Y to the distance X, is 1.5 or more and 20 or less.

8. The semiconductor device according to claim 1, comprising
a collector region of a second conductivity type which is provided on the back surface of the semiconductor substrate, wherein
the distance X is larger than a distance in the depth direction between a peak of a doping concentration of the collector region and the back surface, and is ¼ or less of a thickness of the semiconductor substrate.

9. The semiconductor device according to claim 1, wherein
the first lifetime control region is provided in the buffer region.

10. The semiconductor device according to claim 1, wherein
the buffer region has
a first peak of a doping concentration in which a dopant is phosphorous, and
a sub peak group of a doping concentration which is provided on a side of the front surface with respect to the first peak in the depth direction of the semiconductor substrate and in which a dopant is hydrogen, and
the first lifetime control region is provided on the side of the front surface with respect to the first peak in the depth direction of the semiconductor substrate.

11. The semiconductor device according to claim 1, wherein
the distance Y is 1.5 X or more and ½ or less of a thickness of the semiconductor substrate.

12. The semiconductor device according to claim 1, wherein
the second lifetime control region is provided in the buffer region.

13. The semiconductor device according to claim 1, wherein
the second lifetime control region is provided on a side of the front surface with respect to the buffer region in the depth direction of the semiconductor substrate.

14. The semiconductor device according to claim 1, comprising
a front-surface-side lifetime control region which is provided on a side of the front surface with respect to a center of the semiconductor substrate in the depth direction of the semiconductor substrate is included in the diode portion, and
the front-surface-side lifetime control region is provided to extend from the diode portion to the transistor portion in a trench array direction.

15. The semiconductor device according to claim 1, comprising
an emitter region of the first conductivity type which is provided on a side of the front surface of the semiconductor substrate with respect to the drift region and has a doping concentration higher than that of the drift region, wherein
the emitter region is provided in the transistor portion and the diode portion.

16. The semiconductor device according to claim 1, comprising
an emitter region of the first conductivity type which is provided on a side of the front surface of the semiconductor substrate with respect to the drift region and has a doping concentration higher than that of the drift region, wherein
the second lifetime control region is provided to extend from the diode portion to the transistor portion in a trench array direction.

17. The semiconductor device according to claim 16, wherein
the transistor portion has a boundary region provided adjacent to the diode portion,
the emitter region is also provided in the boundary region, and
the second lifetime control region is provided to extend from the diode portion to a region below the emitter region provided in the boundary region in the trench array direction.

18. The semiconductor device according to claim 16, wherein
the transistor portion has a boundary region provided adjacent to the diode portion,
the emitter region is not provided on the front surface of the boundary region, and
the second lifetime control region is provided to extend from the diode portion to the boundary region in the trench array direction.

19. The semiconductor device according to claim 1, wherein
the second lifetime control region has an extension region extending from a boundary between the transistor portion and the diode portion to an inside of the transistor portion, and
an area of the extension region in a top view is 10% or less of an area of the second lifetime control region in the top view.

20. The semiconductor device according to claim 1, wherein
a ratio I of an active area of the transistor portion to the area of the active portion is 0.1 or more and 0.9 or less.

21. The semiconductor device according to claim 1, wherein
the area of the active portion is 3 mm² or more and 3000 mm² or less.

22. The semiconductor device according to claim 1, wherein
the distance X is larger than 0 μm and smaller than a distance from the front surface of the semiconductor substrate to the back surface of the semiconductor substrate.

23. The semiconductor device according to claim 1, wherein
the distance Y is smaller than a distance from the front surface of the semiconductor substrate to the back surface of the semiconductor substrate.

24. The semiconductor device according to claim 1, wherein
the first lifetime control region is provided on the side of the back surface with respect to a center of the semiconductor substrate in the depth direction of the semiconductor substrate.

25. The semiconductor device according to claim 1, wherein
the second lifetime control region is provided on the side of the back surface with respect to a center of the semiconductor substrate in the depth direction of the semiconductor substrate.

26. A manufacturing method of a semiconductor device including a transistor portion and a diode portion, comprising:
forming a mask on a back surface of a semiconductor substrate on which the transistor portion is provided; and
forming a back-surface-side lifetime control portion by irradiating a lifetime killer on both a region in which the mask is formed and a region in which the mask is not formed, wherein
the forming the back-surface-side lifetime control portion includes forming, in the transistor portion, a first lifetime control region, which is provided on a side of the back surface with respect to a center of the semiconductor substrate in a depth direction of the semiconductor substrate, by implanting the lifetime killer through the mask, and forming, in the diode portion, a second lifetime control region, which is provided on the side of the back surface with respect to the center of the semiconductor substrate in the depth direction of the semiconductor substrate and at a depth different from that of the first lifetime control region, by implanting the lifetime killer without passing through the mask.

27. A manufacturing method of a semiconductor device including a transistor portion and a diode portion, wherein
the semiconductor device includes
a drift region of a first conductivity type which is provided in a semiconductor substrate,
a plurality of trench portions which are provided on a front surface of the semiconductor substrate,
a first lifetime control region which is provided, in the transistor portion, on a side of a back surface of the semiconductor substrate with respect to a center of the semiconductor substrate in a depth direction of the semiconductor substrate, and
a second lifetime control region which is provided, in the diode portion, on the side of the back surface with respect to the center of the semiconductor substrate in the depth direction of the semiconductor substrate and at a depth different from that of the first lifetime control region, the manufacturing method of the semiconductor device comprising:
determining a limit value of an electrical characteristic of the semiconductor device;
determining one or more formation conditions for forming the first lifetime control region or the second lifetime control region;
determining, for the formation condition, one or more relational expressions connecting a distance X (μm) of the first lifetime control region from the back surface in the depth direction and a distance Y (μm) of the second lifetime control region from the back surface in the depth direction such that the electrical characteristic is equal to or less than the limit value, thereby determining a range of an upper limit value and a lower limit value of each of the distance X and the distance Y;
deciding the distance X and the distance Y from the range;
forming the first lifetime control region at a depth of the distance X decided in the deciding; and
forming the second lifetime control region at a depth of the distance Y decided in the deciding.

28. The manufacturing method of the semiconductor device according to claim 27, wherein
when a dose amount for forming the second lifetime control region is defined as D (atoms/cm²),
the distance X and the distance Y satisfy (Mathematical Formula 4) and (Mathematical Formula 5)
$$\\ \begin{matrix}Y > X & ( Mathematical formula 4 )\end{matrix}$$
$$\\ \begin{matrix}Y \leq BX - 27 B + 1.18 \times {10}^{{}_{} - 23} {D}^{{}_{} 2} - 7.02 \times {10}^{{}_{} - 11} D + 56.89 , & ( Mathematical formula 5 )\end{matrix}$$
B determines the dose amount, the distance X, and the distance Y so as to satisfy (Mathematical formula 6) using a ratio I of an active area of the transistor portion to an area of an active portion of the semiconductor device
$$\\ \begin{matrix}B = - 0.139 {e}^{{}_{} 3.9 \vert} . & ( Mathematical formula 6 )\end{matrix}$$

29. The manufacturing method of the semiconductor device according to claim 28, wherein
the ratio I of the active area of the transistor portion to the area of the active portion is 0.1 or more and 0.9 or less.

30. The manufacturing method of the semiconductor device according to claim 28, wherein
the area of the active portion is 3 mm² or more and 3000 mm² or less.

31. The manufacturing method of the semiconductor device according to claim 27, wherein
the distance X is larger than 0 μm and smaller than a distance from the front surface of the semiconductor substrate to the back surface of the semiconductor substrate.

32. The manufacturing method of the semiconductor device according to claim 27, wherein
the distance Y is smaller than a distance from the front surface of the semiconductor substrate to the back surface of the semiconductor substrate.

33. The manufacturing method of the semiconductor device according to claim 26, wherein
the first lifetime control region is provided on the side of the back surface with respect to a center of the semiconductor substrate in the depth direction of the semiconductor substrate.

34. The manufacturing method of the semiconductor device according to claim 26, wherein
the second lifetime control region is provided on the side of the back surface with respect to a center of the semiconductor substrate in the depth direction of the semiconductor substrate.

35. The manufacturing method of the semiconductor device according to claim 26, wherein
the forming the first lifetime control region and the forming the second lifetime control region are performed by one ion implantation through a mask covering the back surface of the semiconductor substrate with a predetermined pattern.
